(19) United States
(12) Patent Application Publication
(10) Pub. No.: US 2026/0286520 A1
(43) Pub. Date: Sep. 24, 2026

(54) A THIN-FILM DEPOSITION APPARATUS REACTION CHAMBER

(71) Applicant: Picosun Oy, Espoo (FI)

(72) Inventors: Timo VÄHÄ-OJALA, Espoo (FI); Tom BLOMBERG, Espoo (FI); Mikko NÄSI, Espoo (FI)

(21) Appl. No.: 19/472,119

(22) PCT Filed: Jun. 13, 2024
(86) PCT No.: PCT/FI2024/050312

§ 371 Date: Oct. 3, 2025

(30) Foreign Application Priority Data
Jun. 21, 2023 (FI) 20235718

(51) Int. Cl. C23C 16/455; C23C 16/44; C23C 16/458

(52) U.S. Cl. CPC C23C 16/45546; C23C 16/4412; C23C 16/45504; C23C 16/4585

(57) ABSTRACT

An apparatus, comprising a main body part of a laminar flow reaction chamber (120) comprising an inlet opening for precursor gas at its front side, an exhaust opening (190) at its rear side, and a lid opening at its top or bottom side, and a substrate holder (140) configured to accommodate a batch of substrates (130), the surfaces of the substrates facing each other thus forming a substrate stack, the substrate holder (140) forming a lid to cover the lid opening.

### TECHNICAL FIELD

The present disclosure generally relates to substrate processing equipment and associated methods. The disclosure relates particularly, though not exclusively, to loading and processing a batch of substrates.

### BACKGROUND

This section illustrates useful background information without admission of any technique described herein representative of the state of the art.

Substrate processing methods can be used, among others, to deposit thin film coatings onto substrates from a vapor phase. For instance, Atomic Layer Deposition (ALD) is a widely used technology for preparing thin films. ALD is based on alternating self-saturating surface reactions on a substrate, wherein different reactants (precursors) provided as chemical compounds or elements, in a nonreactive inert gaseous carrier in some implementations, are sequentially pulsed into a reaction space accommodating a substrate. Deposition of a reactant is typically followed by purging the substrate by inert gas. Precursor-purge cycles are repeated as many times as required for obtaining a film with a predetermined thickness.

Processing conditions inside a reaction chamber of a substrate processing apparatus should be as uniform as possible throughout the reaction chamber to ensure high quality and uniform substrate processing. Non-uniform processing conditions may also result in undesirable increase in resource (precursor) usage and processing time. Particularly, in batch processing where a plurality of substrates is simultaneously processed in the same reaction chamber providing homogeneous processing conditions to each substrate is challenging. A stable and even precursor access and gas flow to all parts of each substrate should preferably be ensured regardless of their position inside the reaction chamber.

There is also an ongoing need to develop improved design of the substrate processing apparatus or its operation as a whole and/or to develop improved design of different parts of the substrate processing apparatus, such as reaction chamber(s) and substrate holder(s) as such.

### SUMMARY

The present disclosure aims to improve the operation of a substrate processing apparatus, to improve certain parts of a substrate processing apparatus, or at least to provide an alternative to existing technology.

Certain embodiments of the present disclosure aim to improve uniform precursor deposition onto substrate surfaces, particularly during batch processing of the substrates. In the batch processing, a plurality of substrates is simultaneously present inside a reaction space for processing. Certain embodiments enable all substrates of a batch to have as similar and as uniform coatings as possible by enabling highly uniform precursor concentration and flow near and across the surfaces of all substrates in a reaction chamber.

The appended claims define the scope of protection. Any examples and technical descriptions of apparatuses, products and/or methods in the description and/or drawings not covered by the claims are presented not as embodiments of the invention but as background art or examples useful for understanding the invention.

According to a first example aspect there is provided an apparatus, comprising:
a main body part of a laminar flow reaction chamber comprising an inlet opening for precursor gas at its front side, an exhaust opening at its rear side, and a lid opening at its top or bottom side; and
a substrate holder configured to accommodate a batch of substrates, the surfaces of the substrates facing each other thus forming a substrate stack, the substrate holder forming a lid to cover the lid opening.

In certain embodiments, the inlet opening is reaction chamber wide or reaction chamber high.

In certain embodiments, the apparatus comprises a throat downstream the inlet opening.

In certain embodiments, the throat is a concave throat. In certain embodiments, the throat is symmetrical. In certain embodiments, the throat is asymmetrical.

In certain embodiments, side walls of the main body part of the reaction chamber curve inwards towards the exhaust opening.

In certain embodiments, side walls are symmetrical. In certain embodiments, side walls are asymmetrical.

In certain embodiments, the side walls of the main body part of the reaction chamber are free from flow obstacles.

In certain embodiments, the main body part of the reaction chamber is monolithic.

In certain embodiments, the substrate holder is monolithic. In certain embodiments, the substrate holder is rotatable within the main body part of the reaction chamber.

In certain embodiments, the substrate holder is configured to accommodate more than 15 substrates, preferably up to 30 substrates.

In certain embodiments, the substrate holder comprises two opposite protruding parts protruding from the substrate holder and being configured to support the substrates.

In certain embodiments, the protruding parts each have an equal spacing for supporting substrates.

In certain embodiments, the protruding parts each have an unequal spacing for supporting substrates.

In certain embodiments, the substrate holder comprises a smooth planar lid part, and the opposite protruding parts protrude from the smooth planar lid part to accommodate substrate(s).

In certain embodiments, the two opposite protruding parts follow the shape of a round substrate.

In certain embodiments, the two opposite protruding parts comprise ridges or grooves to accommodate the substrates.

In certain embodiments, the spacing of the ridges or grooves is equal.

In certain embodiments, the closest distance (or vertical distance) from an outermost substrate to its closest reaction chamber wall (top or bottom wall) is different (or larger) from a closest distance (or vertical distance) between adjacent substrates.

In certain embodiments, the closest distance (or vertical distance) from an outermost substrate to its closest reaction chamber wall (top or bottom wall) is same as a closest distance (or vertical distance) between adjacent substrates.

In certain embodiments, the two opposite protruding parts form vertical elements. In certain embodiments, the ridges or grooves in the vertical elements are configured to accommodate 15-30 substrates as a stack, wherein the planar surfaces of the substrates are facing each other while allowing fluid flow through the stack.

In certain embodiments, the spacing of the ridges or grooves is unequal. In certain embodiments, the spacing of the ridges or grooves is mirrored with respect to a longitudinal axis of the reaction chamber.

In certain embodiments, the spacing of the ridges or grooves is non-symmetrical with respect to the longitudinal axis of the reaction chamber.

In certain embodiments, the substrate holder comprises a base plate. In certain embodiments, a lid of the reaction chamber serves as the base plate.

In certain embodiments, the distance from an upper planar surface of a topmost substrate of the substrate stack to the reaction chamber wall (top or bottom wall) or the baseplate is different than the distance from a lower planar surface of a lowermost substrate to the baseplate or the reaction chamber wall (bottom or top wall).

In certain embodiments, the distance from the upper planar surface of the topmost substrate of the substrate stack to the reaction chamber wall or the base plate is configured to be the same as the distance from the lower planar surface of the lowermost substrate to the baseplate or the reaction chamber wall.

In certain embodiments, the apparatus comprises an exhaust line in or attached to the main body part of the reaction chamber. In certain embodiments, the main body part of the reaction chamber comprises the exhaust line or a portion of the exhaust line.

In certain embodiments, the exhaust line takes a turn. In certain embodiments, the turn is perpendicular to the direction of the laminar flow. In certain embodiments, the turn is substantially 90 degrees.

In certain embodiments, the substrate holder is configured to accommodate substrates having a diameter in the range from 100 mm to 1000 mm, preferably 200 mm, most preferably 300 mm.

In certain embodiments, the substrate holder is removably attachable to a liftable substrate rotating system.

In certain embodiments, the substrate holder is configured to be automatically loadable by a loading robot 1,2 ,3 ,4, or 5 substrates at a time.

In certain embodiments, the substrate(s) is (are) wafer(s) with 3D structures at least on one surface.

According to a second example aspect there is provided a method for substrate processing, comprising:
providing a main body part of a laminar flow reaction chamber comprising an inlet opening for precursor gas at its front side, an exhaust opening at its rear side, and a lid opening at its top or bottom side;
accommodating a batch of substrates in a substrate holder, the surfaces of the substrates facing each other thus forming a substrate stack; and
forming a lid by the substrate holder to cover the lid opening.

In certain embodiments, the method comprises accommodating more than 15 substrates, preferably up to 30 substrates, in the substrate holder.

Different non-binding example aspects and embodiments have been illustrated in the foregoing. The embodiments in the foregoing are used merely to explain selected aspects or steps that may be utilized in different implementations. Some embodiments may be presented only with reference to certain example aspects. It should be appreciated that corresponding embodiments may apply to other example aspects as well.

### BRIEF DESCRIPTION OF THE FIGURES

Some example embodiments will be described with reference to the accompanying figures, in which:

FIGS. 1a and 1b show a schematical cross-sectional side view of a substrate processing apparatus in a loading position and in a processing position, respectively, according to certain embodiments;

FIGS. 2a and 2b show a schematical cross-sectional side view of another substrate processing apparatus in a loading position and in a processing position, respectively, according to certain embodiments;

FIGS. 3a and 3b show a schematical cross-sectional side views of still another substrate processing apparatus in a loading position and in a processing position, respectively, according to certain embodiments;

FIG. 4 shows a schematical top view of a reaction chamber and a fluid distributor according to certain embodiments;

FIG. 5 shows a schematical cross-sectional side view of a liftable substrate rotating system according to certain embodiments;

FIGS. 6a and 6b show schematical cross-sectional views of a fluid distributor at different orientations according to certain embodiments;

FIGS. 7a and 7b show a schematical cross-sectional side views of a transition region section of a fluid distributor having symmetrical and non-symmetrical structure, respectively, according to certain embodiments;

FIG. 8 shows a schematical side view of a fluid distributor with a detachable cover according to certain embodiments;

FIGS. 9a-9c show schematical side, front, and top-view cross-sections of a substrate processing apparatus configured to accommodate high stack of substrates according to certain embodiments;

FIGS. 10a-10d show structural drawings of a substrate processing apparatus according to certain embodiments configured to accommodate a high stack of substrates. In FIGS. 10a and 10b substrates are omitted, in FIGS. 10c and 10d the substrates are shown;

FIGS. 11a and 11b show schematical side view and a cross-section, respectively, of a substrate processing apparatus configured to accommodate a high stack of substrates according to certain embodiments;

FIGS. 12a and 12b show schematical side view and a cross-section, respectively, of another substrate processing apparatus configured to accommodate a high stack of substrates according to certain embodiments;

FIG. 13 schematically shows a cross section of a substrate holder according to certain embodiments configured to accommodate up to 30 substrates;

FIGS. 14-16 show a perspective drawing of substrate holder for a substrate processing apparatus according to certain embodiments;

FIG. 17 shows a perspective drawing of a main body part of a reaction chamber according to certain embodiments;

FIGS. 18a-18c schematically shows detailed sections of a part of a substrate holder for a substrate processing apparatus according to certain embodiments;

FIG. 19 shows a substrate processing system according to certain embodiments;

FIG. 20 shows a flow chart of substrate processing according to certain embodiments; and

FIG. 21 shows a flow chart of substrate processing according to certain other embodiments.

### DETAILED DESCRIPTION

In the following description, like reference signs denote like elements or steps.

Certain embodiments described in more detail below, describe a substrate processing apparatus comprising a reaction chamber for accommodating substrates arranged with their main surfaces (or planar surfaces/side faces) adjacent to each other. Certain embodiments disclose a fluid distributor configured to direct a fluid stream into the reaction chamber. In certain embodiments, the flow established at an entrance to the reaction chamber and propagating through a length of said reaction chamber, between the substrate surfaces, is laminar. In certain embodiments, a liftable substrate rotating system is configured to transfer the substrates between a processing position and a loading position and to rotate the substrates in the laminar flow (at the processing position). In certain embodiments, the substrate processing apparatus is configured to accommodate and process a batch of up to 25-30 substrates (in a substrate holder). A liftable substrate rotating system is used to move the substrates. In certain embodiments, the substrate processing apparatus is configured to be implemented as a substrate processing system or as a part of a substrate processing system.

Laminar flow or streamline flow or lateral flow is defined, in the context of the present disclosure, as a flow void of turbulence (without turbulent velocity fluctuations). The laminar flow constantly progresses to one direction, for instance from an entrance of a reaction chamber towards an exhaust outlet. Lateral or vertical expansion of the lateral flow or deviation from the shortest linear path may occur as long as the flow constantly proceeds towards the predetermined direction. That is, laminar flow in the context of this application may curve but not return or flow backwards. The laminar flow comprises lateral spreading of fluid within the reaction chamber. In laminar flow, fluid layers/streams slide in parallel in an absence of vorticity, swirls or currents. For clarity, we note that the present invention should not be confused with any kind of venturi applications neither in terms of structural details nor with regard to functionality. The present disclosure does not utilize incompressible liquids, but gaseous media in conditions of high vacuum and, in most instances, at elevated temperature.

In the apparatus described herewith, laminar flow is supported for both precursor fluid flow and for inert fluid flow, the latter occurring, in ALD, during purge periods, for example. Hence, the substrates arranged in the substrate holder encounter a laminar flow inside the reaction chamber. Advantageously, in certain embodiments, potential directional effects of the unidirectional flow, e.g., differences or defects in leading edge and trailing edge deposition, may be mitigated by rotating the substrate. That is, fluid flow is directed to a substrate(s) equally from all directions during the deposition process due to turning of the substrate(s).

Certain embodiments according to the present disclosure relate to a substrate processing apparatus. Substrate processing apparatuses according to certain embodiments are shown in the accompanying figures. The substrate processing apparatuses are configured to exploit principles of vapor-deposition based techniques. In preferred embodiments, the substrate processing apparatus is an Atomic Layer Deposition (ALD) apparatus.

In ALD, at least one substrate is typically exposed to temporally separated precursor pulses in a reaction vessel to deposit material on the substrate surfaces by sequential self-saturating surface reactions. In the context of this application, the term ALD comprises all applicable ALD based techniques and any equivalent or closely related technologies, such as, for example the following ALD sub-types: MLD (Molecular Layer Deposition) plasma-assisted ALD, for example PEALD (Plasma Enhanced Atomic Layer Deposition) and photon-enhanced Atomic Layer Deposition (known also as flash enhanced ALD).

In further embodiments, the substrate processing apparatus may be applied to other deposition technologies, such as Physical Vapor Deposition (PVD) and for Plasma-Enhanced Chemical Vapor Deposition (PECVD) processes.

In certain embodiments, the substrate processing apparatus is an atomic layer etching (ALE) apparatus.

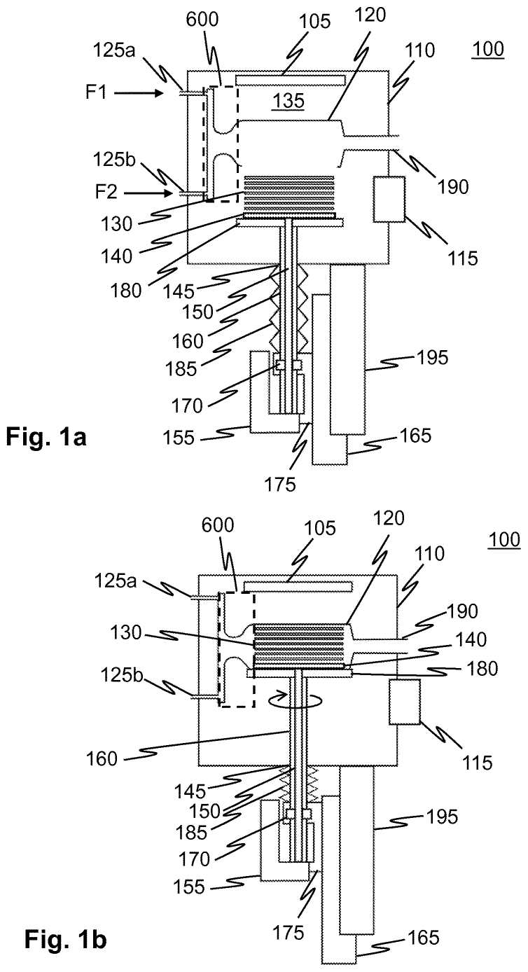

FIGS. 1a and 1b show a schematical cross-sectional side view of a substrate processing apparatus in a loading position and in a processing position, respectively, according to certain embodiments. In the loading position, substrates 130 are outside of the reaction chamber 120. In the processing position, the substrates 130 are at least partially within the reaction chamber 120. In the embodiments according to FIGS. 1a-1b, the substrates 130 are below the reaction chamber (within an intermediate space 135) at the loading position. Accordingly, the substrates 130 are configured to enter the reaction chamber 120 from below when moved to the processing position.

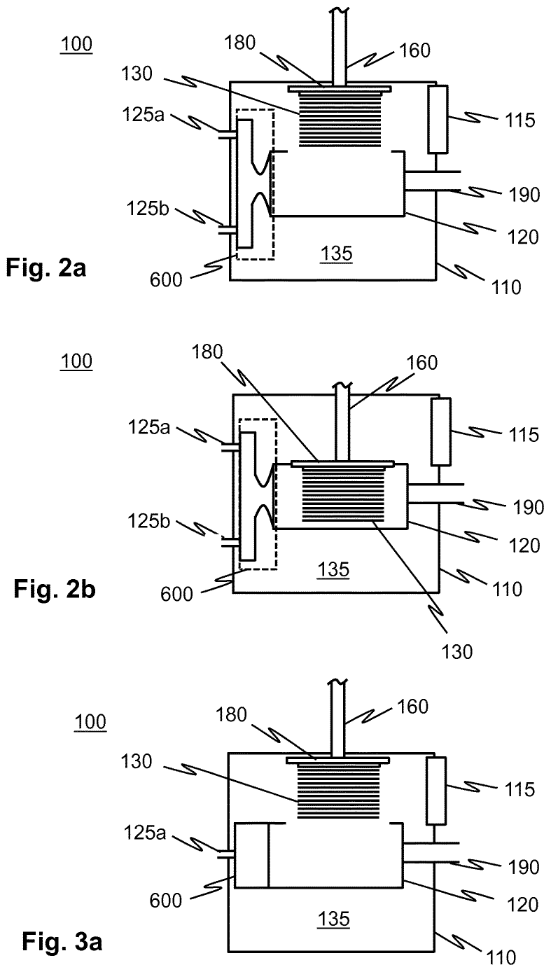

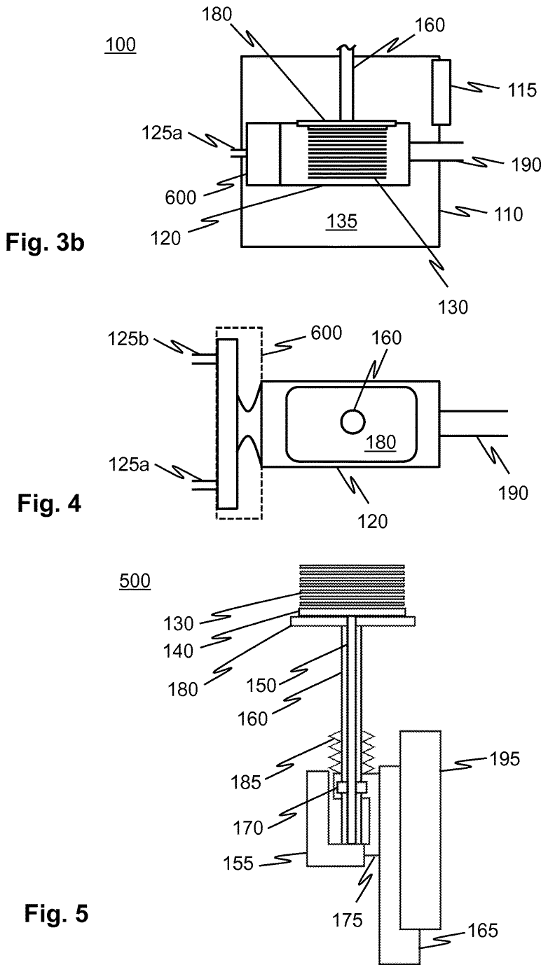

FIGS. 2a-2b and 3a-3b show a schematical cross-sectional side view of another substrate processing apparatuses at a loading position and at a processing position, respectively, according to certain embodiments. As a difference from the embodiments according to FIGS. 1a-1b, in the embodiments according to FIGS. 2a-3b the substrates 130 are located above the reaction chamber 120 (within the intermediate space 135) at the loading position. Accordingly, the substrates 130 are configured to enter the reaction chamber 120 from above when moved to the processing position. At the processing position, the substrates 130 are at least partially within the reaction chamber 120.

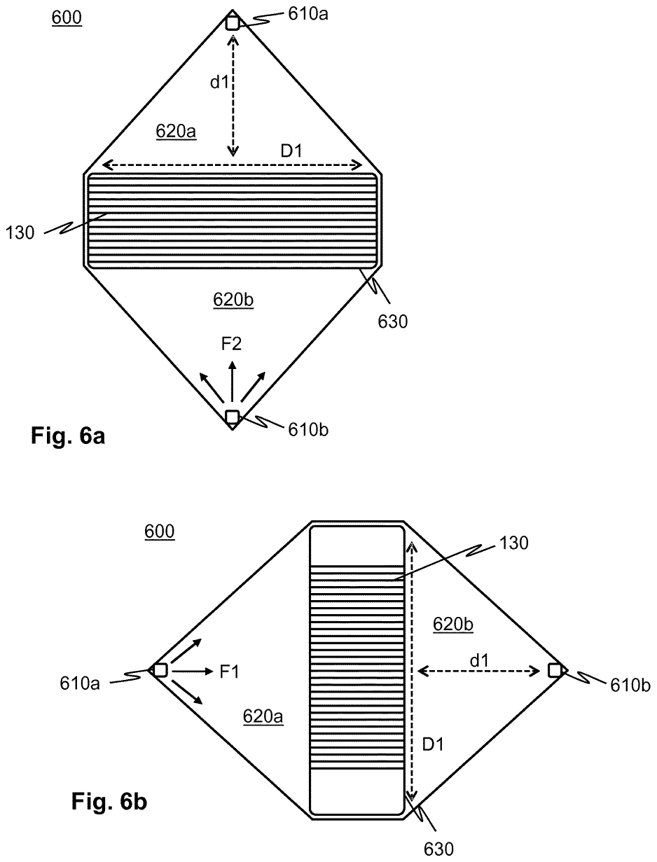

As a further difference, in a substrate processing apparatus 100 according to the embodiments of FIGS. 1a-2b the fluid distributor 600 is arranged such that feedlines 125a, 125b are vertically separated, e.g., located at a same vertical line. In such cases, expansion regions 620a, 620b of the fluid distributor 600 (see FIG. 6a) are configured, in particular, to provide horizontal distribution of the fluid flow. In certain embodiments, the fluid distributor 600 is arranged such that the feedlines 125a, 125b are horizontally separated, e.g., located at a same horizontal plane, as shown, e.g., in FIGS. 3a-3b and 4. Note that only one feedline 125a is visible in FIGS. 3a-3b since the second feedline 125b is located behind the first feedline 125a in the shown side-view. The top view of FIG. 4 shows both feedlines 125a and 125b located at the same horizontal plane. In such cases, the expansion regions 620a, 620b of the fluid distributor 600 (see FIG. 6b) are configured to provide, in particular, vertical distribution of the fluid flow. The fluid distributor 600 is further discussed in in relation to the FIGS. 6-8. Advantageously, lateral fluid distribution (in horizontal plane) or the vertical fluid distribution upon entry to the reaction chamber may be improved by selecting a suitable fluid distributor 600 orientation.

FIG. 4 shows a schematical top view of a reaction chamber and a fluid distributor according to certain embodiments. The reaction chamber 120 shown in FIG. 4 could be for instance the reaction chamber 120 of the substrate processing apparatus of FIGS. 3a-3b.

The substrate processing apparatus 100 comprises a reaction chamber 120 for processing substrates 130. The reaction chamber 120 may also be referred to as an inner chamber. The reaction chamber 120 is preferably implemented as a flat, elongated vessel that dimensionally conforms to a predetermined number of substrates 130 received thereinto. This way efficient and equal gas flow is enabled both between the substrates 130 arranged onto a holder 140 (through the substrate stack) and across the outer surfaces of the peripheral substrates 130 of the batch (around the substrate stack). That is, all the planar surfaces of the substrates 130 in the substrate holder 140 are subject to substantially similar conditions and thus may be processed equally.

An external housing 110 at least partially accommodates the reaction chamber 120 (or surrounds the reaction chamber 120 either partially or wholly). The external housing 110 may also be referred to as an outer chamber. An intermediate space 135 is formed between the outside walls of the reaction chamber 120 and the inside walls of the external housing 110. In certain embodiments, an intermediate space 135 established by an interior of said external housing 110 is maintained under vacuum and referred to as a vacuum chamber.

The external housing 110 comprises a closable opening 115, e.g., a load lock, for loading and removing of substrates 130 and/or the substrate holder 140 to/from the external housing 110 when the liftable substrate rotating system 500 is at the loading position. At the loading position, the substrate holder 140 and the substrates are outside the reaction chamber 120 and within the intermediate space 135. In the processing position the substrates 130 are at least partially within the reaction chamber 120.

A rotatable substrate holder 140 accommodates the substrates 130 as a stack, the planar surfaces of the substrates (or wafers) 130 adjacent to each other (or facing each other), such that fluids may flow between the planar substrate 130 surfaces, i.e., through the substrate stack. A rotation motor 155 drives the rotating of the substrate(s) 130 and the substrate holder 140 during the processing in a laminar flow to enable equal processing of the substrates 130 and to improve processing quality. Advantageously, fluid flow access to all areas of the substrates 130 during processing is improved.

Arranging the substrates 130 in the reaction chamber side-by-side in a stack and closely adjacent to each other (nevertheless leaving a gap in between) contributes to establishing the laminar flow between said substrates 130. In practice, the reaction chamber 120 can be provided in different sizes to dimensionally conform, in a non-limiting manner, to a variety of standard substrates 130, such as disc-shaped wafer substrates having a diameter ranging within 25-300 mm. The reaction chamber 120 (and the entire reactor installation 100, accordingly) can be further modified to incorporate the substrates 130, whose diameter exceeds 300 mm, preferably in the range from 100 mm to 1000 mm. By rotating the substrates 130 during the deposition process, effects of uneven flow and potential fluctuations may be taken into account and mitigated.

Precursors and inert gases (fluid flows F1 and F2 in FIG. 1a) are delivered to the reaction chamber via feedlines 125a, 125b in a fluidic form. The reactive fluid flowing through the feedlines 125a, 125b is preferably a gaseous substance comprising a predetermined precursor chemical optionally carried by or mixed with an inert carrier or fluid. The inert carrier or fluid is a fluid, preferably gas, such as nitrogen (N₂), argon (Ar) or any other suitable gaseous medium that possesses essentially zero reactivity towards the precursors (reactants) and the reaction products. Inert fluid or carrier gas is supplied from a separate source or sources.

In certain embodiments, the precursor fluid flow is delivered to the reaction chamber 120 by means of at least one feedline 125a, 125b. The embodiments of FIGS. 1-4, show two feedlines but different number of feedlines is possible. In certain embodiments, the substrate processing apparatus 100 comprises 1, 2, 3, or 4 feedlines. In certain embodiments, the number of feedlines 125 is connected to a variety of precursor sources, and inert gas sources or supplies to be provided to the reaction chamber 120.

It is preferred that the precursor fluid is delivered to the reaction chamber 120 in a plurality of sequential pulses. The fluid distributor 600 (highlighted with a dashed box in FIGS. 1a-2b) receives the fluid from the feedlines 125a, 125b and establishes a laminar flow through the reaction chamber 120.

The laminar fluid flow having passed through the substrates 130 and the reaction chamber 120 converges upon exit from the reaction chamber 120 to form an exhaust flow. The exhaust flow is discharged from the reaction chamber 120 through an exhaust conduit 190. The exhaust conduit is located opposite the fluid distributor 600 on the opposite side of the reaction chamber 120.

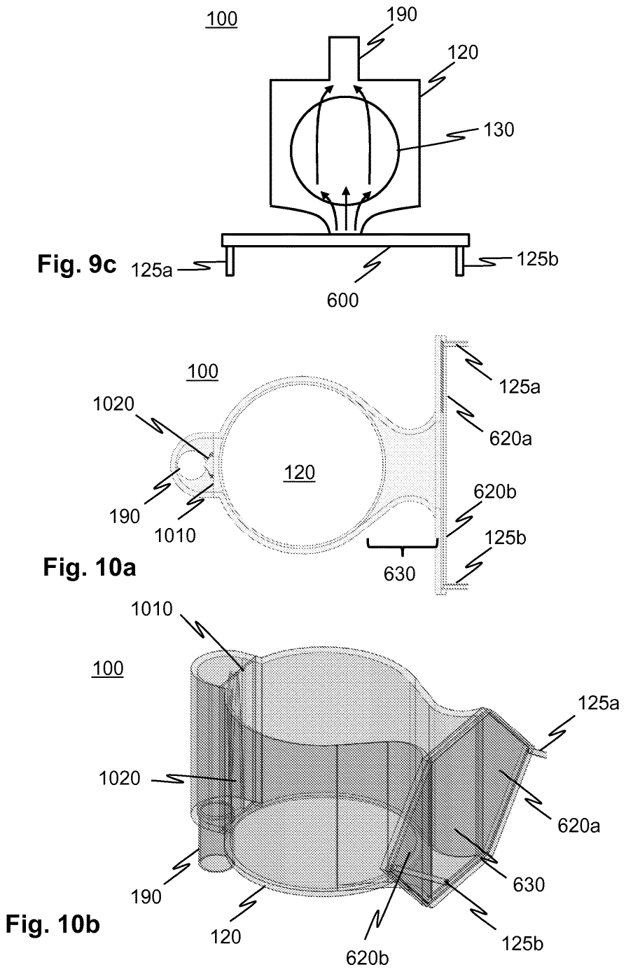

The exhaust flow may comprise, for example, excess carrier, precursor, and reaction products. In certain embodiments, a vacuum pump is connected to the exhaust conduit 190 and used to remove the fluidic substances either continuously during the entire deposition process or at predetermined times. A vacuum pump is shown, for instance, in FIG. 9a.

Heater(s) or heating element(s) 105 placed inside the external housing 110 are configured to adjust processing temperature. One heating element 105 is shown in FIGS. 1a and 1b but other number of heating elements 105 is possible, too.

In certain embodiments, the reaction chamber 120 is kept under vacuum during operation, loading and unloading, whereupon pressure in the reaction chamber 120 is maintained at a level below 1 kPa (10 mbar), preferably, 10 Pa (0.1 mbar). During loading and unloading, at the loading position, the reaction chamber 110 is in fluid communication with the intermediate space 135. In certain embodiments, the reaction chamber 120 is in fluid communication with the intermediate space 135 during processing. That is, in certain embodiments, the reaction chamber 120 is not sealed during processing at the processing position. That is, in certain embodiments, the reaction chamber 120 is partially open. In certain embodiments, pressure in the reaction chamber 120 is set at the same level as the ambient pressure. In certain embodiments, pressure in the reaction chamber 120 is equal to the pressure in the intermediate space 135.

In certain embodiments, the pressure of the intermediate space/the vacuum chamber 110 is maintained at a level of at least 1 kPa (10 mbar). Preferably, the pressure in the intermediate space 135 is maintained at a level exceeding 1 kPa, to establish a pressure difference between the interior of the reaction chamber 120 (typically, less than 100 Pa) and the interior of the vacuum chamber 110 during substrate processing. In certain embodiments, the pressure in the intermediate space 135 is maintained higher in comparison to the pressure in the reaction chamber 120 during substrate processing. In certain embodiments, depending on particular operating parameters, precursors and/or reaction conditions, the pressure in the intermediate space 135 is maintained lower than in the reaction chamber 120 or the same as in the reaction chamber 120 during substrate processing.

A liftable substrate rotating system 500 is used to move the substrates 130 inside the thin-film deposition apparatus 100 between a loading position (e.g., FIG. 1a) and a processing position (e.g., FIG. 1b). A liftable substrate rotating system 500 according to certain embodiments is schematically shown in FIG. 5. The liftable substrate rotating system 500 according to the embodiments of FIG. 5 may be installed, for example, to a thin-film deposition apparatus 100. In certain embodiments, the liftable substrate rotating 500 system is attached, as a modular unit, for example, to a (sub-)frame 195 or a bracket of the thin-film deposition apparatus 100. By attaching the liftable substrate rotating system 500 directly to the apparatus 100, the liftable substrate rotating system 500 may be effectively supported and aligned with respect to (the openings of) the external housing 110 and the reaction chamber 120. The liftable substrate rotating system 500 may be attached to the (sub-)frame 195, for example, by bolts.

In certain embodiments, the liftable substrate rotating system 500 comprises at least a lifting motor 165, a lifting axle 160, a rotation motor 155, and a rotating axle 150. In certain embodiments, the system 500 comprises a lid 180, or the system 500 is integrated to a reaction chamber lid 180. In certain embodiments, the system 500 comprises a substrate holder 140. In certain embodiments, the liftable substrate rotating system 500 comprises linear module 175. In certain embodiments, the liftable substrate rotating system 500 comprises vacuum bellows 185. In certain embodiments, the liftable substrate rotating system 500 comprises a vacuum seal feedthrough 170. In certain embodiments, the vacuum seal feedthrough 170 is a ferrofluidic vacuum seal feedthrough. Accordingly, in certain embodiments, the apparatus 100 or the liftable substrate rotating system 500 comprises a dynamic sealing for a feedthrough through the vacuum chamber 110 wall. In certain embodiments, the substrate holder 140 is replaceable. Substrate(s) 130 may be loaded to the substrate holder 140 so that they can be moved by the liftable substrate rotating system 500.

The liftable substrate rotating system 500 coupled with a thin-film deposition apparatus 100, according to embodiments, enables transferring substrates 130 vertically between a processing position and a loading position and their efficient processing. The substrates 130 are vertically moved to be accommodated inside a reaction chamber 120. At the processing position the liftable substrate processing system 500 is configured to rotate the substrates in the reaction chamber 120 during the substrate processing. The lid 180 is configured to seal the chamber 120. The substrate holder 140 and the substrates 130 are rotatable inside the reaction chamber 120 by the rotation motor 155. Rotation of the substrate stack combined with the laminar flow established by a fluid distributor mitigates the effects of processing defects. Hence, homogeneous deposition may be promoted by reducing non-homogenous fluid distribution and turbulence.

The lifting motor 165 is fixed and remains stationary with respect to the (sub-)frame 195 of the thin-film deposition apparatus 100. The lifting motor 165 is preferably a servo motor. The lifting motor 165 drives the linear module 175, and the lifting axle 160 connected to it, up and down, i.e., vertically. That is, the lifting axle 160 is connected to the lifting motor 165 via the linear module 175. Accordingly, in certain embodiments, the position of other parts of the liftable substrate rotating system 500 connected to the linear module 175 and/or the lifting axle 160, apart from the lifting motor 165, is also vertically adjustable. When the substrates 130 and the substrate holder 140 are at least partially within the reaction chamber 120, the liftable substrate rotating system 500 is at the processing position. When the substrates 130 and the substrate holder 140 are (fully) outside the reaction chamber 120, the liftable substrate rotating system 500 is at the loading position. In certain embodiments, for example, if the substrate stack is high, the substrate holder 140 may reside partly inside of the reaction chamber 120 at a loading position.

The plurality of substrates 130 may be arranged on the rotatable substrate holder 140 for processing. The substrates 130 are preferably flat planar substrates, such as wafers comprising two planar surfaces on the opposite sides of the wafer. In certain embodiments, the substrate holder 140 is a removable part, separate from the remaining thin-film deposition apparatus 100 and separate from the liftable substrate rotating system 500. In certain embodiments, the substrate holder 140 is a fixed, non-removable part of the liftable substrate rotating system 500. In certain embodiments, the substrate holder 140 is a fixed, non-removable part of the substrate processing apparatus 100.

The substrate holder 140 is configured to accommodate a batch of substrates, a plurality of substrates aligned with their planar surfaces parallel and adjacent to each other, i.e., as a stack of substrates with empty spaces in between the planar substrate surfaces to allow (laminar) fluid flow in between the substrates 130. The substrate holder 140 aligns the planar substrate surfaces parallel to the longitudinal axis of the reaction chamber 120. The longitudinal axis of the reaction chamber 120 is the axis along the direction of the fluid flow from the (fluid) entrance of the reaction chamber 120 to the exhaust conduit 190. For instance, in the embodiments of FIGS. 1-3, the fluid flow and the longitudinal axis of the reaction chamber 120 are essentially horizontal.

One or more substrates 130 may be accommodated by the substrate holder 140. Preferably, the substrate holder 140 accommodates a plurality of substrates 130 to be processed as a single batch. In certain embodiments, the substrates 130 are loaded to the substrate holder 140 one substrate at a time. In certain embodiments, substrates 130 are loaded to the substrate holder 140 more than one substrate 120 at a time. In certain embodiments, substrates 130 are loaded to the substrate holder 1, 2, 3, 4, or 5 substrates 130 at a time. In certain embodiments, substrates 130 are loaded to the substrate holder 140 up to 5 substrates at a time. In certain embodiments, the loading is performed by a loading robot.

In certain embodiments, the substrate holder 140 comprises vertical elements protruding from a base plate or from a lid part. The vertical elements are configured to support the substrates 130 so as to form a stack of substrates. In certain embodiments, the substrates 130 are fitted into a receiving structure or groove(s) provided by said vertical elements. In certain embodiments, the substrate holder 140 comprises two or more vertical elements. Substrate holders 140 according to certain embodiments are further discussed later in this description.

In certain embodiments, the substrate holder 140 is connected to a first end (upper end in FIG. 1) of a rotating axle 150. The substrate holder 140 is configured to be rotatable by the rotating axle 150. In certain embodiments, the substrate holder 140 may be detached from the first end of the rotating axle 150 and removed from the thin-film deposition apparatus 100, for example, for cleaning or to be replaced by another substrate holder 140. The rotating axle 150 is configured to be rotatable by the rotation motor 155.

The rotation motor 155 is connected to a second end (lower end in FIG. 1) of a rotating axle 150. The rotation motor 155 is configured to rotate the substrate holder 140 and the accommodated substrate(s) 130 by rotating the rotating axle 150. The rotating axle 150 is configured to rotate the substrate holder 140, and the substrates 130 therein, in the plane of the substrate surfaces. That is, the rotating axle 150 is directed perpendicular to the planar surfaces of the substrates 130 and perpendicular to the longitudinal axis of the reaction chamber 120.

The rotation enables more even conductance across the entire surface(s) of the substrate(s) 130. The conductance is defined as a fluid flow rate divided by a pressure drop (C=q/dp). The flow rate varies depending on the flow path. In the case of circular substrates 130, such as wafers, fluid flow travels more easily on the sides as there is less restriction caused by the substrates 130, whereas the smallest conductance and thus smallest chemical dosage is typically present in the path across the middle of the wafer. This is a fundamental problem, as the highest dosage would be needed in the middle of the wafer where most of the surface area to be processed is. The liftable substrate rotating system 500 and the rotating the substrates 130 alleviates the problem of uneven conductance across the substrates 130. The rotating axle 150 is housed within a lifting axle 160. The rotating axle 150 is longer than the lifting axle 160 and extends through the entire length of the lifting axle 160. The first end of the rotating axle 150 extends from the first end of the lifting axle 160 and connects to the bottom of the substrate holder 140 through an opening of the lid 180. The lid 180 is attached to and supported by the first end (upper end in FIGS. 1a-1b, lower end in FIGS. 2a-3b) of the lifting axle 160. In other words, the rotating axle penetrates through the lid 180. The lid 180 is separate from the substrate holder 140 and does not rotate. The lid 180 is fixedly coupled to the first end of the lifting axle 160, which surrounds the rotating axle 150.

The second end of the rotating axle 150 is connected to a rotation motor 155 through the second open end of the lifting axle 160. The rotation motor 155 is preferably a servo motor. The rotation motor 155 is also connected to and supported by the second end of the lifting axle 160 and/or the linear module 175. Hence, the rotation motor 155 is vertically movable with the lifting axle 160 and the linear module 175 as a part of the movable lifting system 500.

The substrate holder 140 and the substrate(s) 130 are rotated by the rotation motor 155 at a desired rotation speed during substrate processing. In certain embodiments, the rotation speed is constant through the entire deposition process. In certain embodiments, the rotation speed is varied depending on the characteristics of the precursor to be deposited. Rotation speed may be relatively slow. In certain embodiments, the rotation speed is half a rotation (180 degrees) per an entire deposition run (that includes all deposition cycles required to deposition the film). The rotation speed may be relatively fast. In certain embodiments, the rotation speed is one full rotation (360 degrees) during a single chemical pulse. In certain embodiments, the substrate holder 140 and the substrate(s) 130 are rotated stepwise, e.g. 90 or 180 degrees at a time (e.g., with an indexing mechanism). In certain embodiments, the substrate holder 140 and the substrate(s) 130 are rotated 180 degrees halfway during deposition or 90 degrees at every quarter of a full deposition cycle number.

Rotating of disc-shaped substrates 130, such as wafers, inside the reaction chamber 120 is advantageous for the deposition uniformity of the coatings. Through rotation, different parts of the substrates 130 may equally interact with the laminar fluid flow and position-related differences during the deposition process may be minimized. In other words, the laminar fluid flow is not directed to a substrate from one side only because the substrate is rotated.

Advantageously, the rotation motor 155 (as well as the lifting motor 165 of the lifting axle 160) is located outside the reaction chamber 120 and the external housing 110. This way the reaction chamber 120 and the external housing 110 can be kept compact and motors for rotation and/or lifting 155, 165 do not have to be fitted inside the reaction chamber 120 or the external housing 110. Accordingly, the maintenance and replacement of the motors 155, 165 is made easier. Further, the placement of the motors 155, 165 allows the reaction chamber 120 and the external housing to be kept compact as the chambers 120, 110 do not need to be designed to accommodate the motors. Consequently, the number of components present inside the chambers 110, 120 required for rotating and moving the substrate holder 140, and potentially affecting fluid flow and requiring cleaning, may be kept low. Accordingly, the reaction chamber 120 and external housing 110 may be designed and manufactured to be more compact and to better conform to the substrate 130 dimensions. Thus, processing quality may be improved, risk of contamination reduced, and the maintenance made more accessible and straightforward.

The lifting axle 160 is structurally a hollow rod or a tube configured to accommodate the rotating axle 150 such that the rotating axle 150 is rotatable within the lifting axle 160 independently of the lifting axle 160. The lifting axle 160 does not rotate. The lifting axle 160 is configured to be vertically movable by a lifting motor 165. Accordingly, the lid 180, rotating axle 150, substrate holder 140, and the substrate(s) 130 are configured to move with the lifting axle 160. In certain embodiments, the lifting axle is connected to a tray of a linear module 175, for instance, by a fixing bracket. The tray of the linear module 175 is configured to be vertically movable by the lifting motor 165. Thus, the lifting motor 165 is configured to move the lifting axle 160 by moving the tray of the linear module 175 up and down.

In certain embodiments, the lid 180 is configured to seal the reaction chamber 120 at the processing position. Thus, the lid 180 is configured to form a part of the wall of the reaction chamber 120. Therefore, fluid communication between the reaction chamber and the intermediate space 135 is prevented and the vacuum conditions at the two volumes may be separately adjusted during processing. In certain embodiments, the lid 180 comprises alignment/sealing tension springs located as its four corners to secure tight and even fit against the reaction chamber 120 at the processing position. The lifting axle 160 is configured to carry the lid 180 and the sealing pressure load.

In certain embodiments, the lid 180 does not seal the reaction chamber 120 at the processing position. That is, the lid 180 is configured to stay slightly ajar from the reaction chamber 120 walls. Thus, the reaction chamber 120 remains in fluid connection with the intermediate space 135 during processing. In certain embodiments, the opening gap between the lid 180 and the reaction chamber 120 at the processing position is at most 1 mm. In certain embodiments, the gap is 0.1 mm. In certain embodiments, the gap is in the range of 0.02-0.8 mm. Advantageously, the narrow gap enables establishing and controlling the pressure difference between the reaction chamber and the intermediate space 135 even though a fluid communication between the two spaces remains. Such configuration is advantageous and preferred for deposition processes involving, for instance, non-ideal ALD chemistries.

Non-ideal ALD chemistries include, but are not limited to, slowly saturating surface reaction, decomposition component in the surface reaction, or surface site poisoning effect in the chemistry or other anomalies. Examples of non-ideal ALD chemistries include thermal decomposition of metal organic Amidinate precursors such TemaHf, slowly saturating surface reaction for example water reactions, surface site poisoning effect in the TiCL based chemistries.

A vacuum seal feedthrough 170 (which may reside inside or attached to the lifting axle 160) is configured to allow rotating of the rotating axle 150 independently of the (surrounding) lifting axle 160 while preventing vacuum leakage. In certain embodiments, the vacuum seal feedthrough 170 comprises a ferrofluidic vacuum feedthrough. In other embodiments, instead of implementing a ferrofluidic feedthrough, magnetic coupling may be used to transfer rotation from a surrounding atmosphere to vacuum. In yet other embodiments, the rotation motor 155 may be positioned within vacuum.

The lifting axle 160, and the rotating axle 150 inside it, enter the external housing 110 through a chamber feedthrough 145. The vacuum bellows 185 is connected to the chamber feedthrough 145 from their first end (upper end in FIG. 1a-b1) and to the upper surface of the linear module 175 from the second end (lower end in FIG. 1a-1b). The vacuum bellows 185 enables vertical movement of the lifting axle 160 with respect to the external housing 110 and chamber feedthrough 145 without compromising the vacuum conditions inside the external housing 110. The chamber feedthrough 145 is arranged to allow the vertical movement of the lifting axle 160 through it without compromising the vacuum conditions inside the intermediate space.

In certain embodiments, to reach loading position (FIG. 1a), the lifting motor 165 drives the lifting axle 160 downwards such that the substrate holder 140 is lowered from the reaction chamber 120 towards the external housing 110. In certain embodiments, the substrate holder 140 is lifted upwards above the reaction chamber 120 to reach a loading position (e.g., FIGS. 2a-3b). Consequently, at the loading position, the reaction chamber 120 is in fluid communication with the external housing 110. At the loading position, the rotation motor 155 does not rotate the rotating axle 150 (and, consequently, the substrate holder 140). The substrate(s) 130 can be loaded to (or removed from) the substrate holder 140 through the opening 115 located on the wall of the external housing 110 when at the loading position. The opening 115 is sealable, for example, by a door and may comprise, for example, a load lock.

In certain embodiments, (e.g. FIG. 1b), the lifting motor 165 drives the lifting axle 160 up such that the substrate holder 140 is lifted from the external housing 110 to the reaction chamber 120 to reach the processing position. In certain embodiments, the substrates 130 are lowered to the processing position. In certain embodiments, the lid 180 seals the reaction chamber 120 at the processing position. Thus, the fluid communication between the reaction chamber 120 and the external housing 110 is prevented. In certain embodiments, the lid 180 does not seal the reaction chamber 120 at the processing position. FIGS. 6a and 6b show schematical cross-sectional views of a fluid distributor 600 at different orientations according to certain embodiments. The fluid distributor 600 is viewed from the direction of feedlines 125a, 125b towards the reaction chamber 120 and along the longitudinal axis of the reaction chamber 120. The apparatus 100, in the embodiment of FIGS. 6a-6b is in the processing position, i.e., the substrates 130 are located inside the reaction chamber 120 and are visible through the transition region 630 of the fluid distributor 600.

The fluid distributor 600 is configured to expand (within the fluid distributor 600) a fluid flow received from point source(s), that is, inlets 610a, 610b in FIGS. 6a-6b, to the width of the reaction chamber 120 before the fluid flow enters the reaction chamber 120. In certain embodiments, see, e.g. FIG. 6b, the fluid distributor 600 is configured to expand the fluid flow to the height of the reaction chamber 120. The purpose of the fluid distributor 600 is to ensure effective mixing of the fluid flows delivered through the feedlines 125a, 125b and to establish a laminar flow of fluid(s) to perpetuate through the reaction chamber 120. Therefore, efficient spreading of the fluid flow to the reaction chamber 120 may be improved. Prior to entering the reaction chamber 120, the reactive fluid(s) delivered through the number of feedlines 125a, 125b are received into the fluid distributor 600. The plurality of inlets 610a, 610b are connected to the at least one feedline 125a, 125b. The fluid distributor 600 comprises the expansion regions 620a, 620b. The fluid distributor 600 comprises a transition region 630.—The expansion regions 620a, 620b together form an expansion volume. The height (perpendicular to the fluid flow direction across the expansion regions 620a, 620b) of the expansion volume is preferably essentially constant across the interior of the expansion volume.

In the embodiments according to of FIGS. 6a-6b, the expansion regions 620a, 620b are separated by the transition region 630, but provided under a common cover 810 (note that the cover 810 is not visible in FIGS. 6a-6b as the fluid distributor 600 therein is viewed through the cover 810). Each said expansion region 620a, 620b comprises at least one inlet 610a, 610b, respectively. Through the inlets 610a, 610b fluid flows F1, F2 are received into the expansion regions 620a, 620b, respectively.

The expansion regions 620a, 620b are configured to provide respective fluid flows that meet at the transition region 630. The respective flows within the opposite expansion regions 620a, 620b are substantially 2-dimensional flows (lacking a component in the length direction of the reaction chamber 120. The fluid distributor 600 of an apparatus 100 allows said respective fluid flows that meet at the transition region 630 to turn, preferably substantially 90 degrees, towards the reaction chamber 120 as a combined flow.

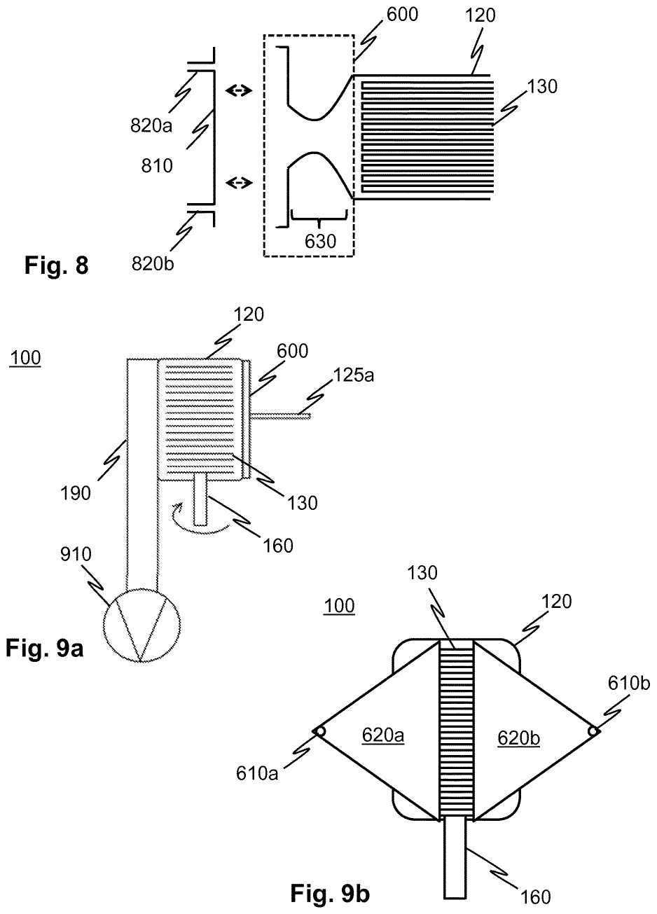

The expansion volume formed by the expansion regions 620a, 620b can be optionally formed of a separate part joined to the reaction chamber 120 by standard techniques, such as welding, for example. Hence, in some instances, the expansion volume can be provided as a removable and replaceable compartment. The cover 810 can be supplied as an integral (inseparable) part of the expansion volume; or, alternatively, the cover part 810 can be provided as a separate, detachable part (for facilitating maintenance, for example). The cover 810 is shown in FIG. 8.

The transition region 630 connects the expansion regions 620a, 620b to the reaction chamber 120. The transition region 630 is formed by a zone between said expansion volume comprising the expansion regions 620a, 620b and the reaction chamber 120 optionally comprising a number of appliances, such as additional flow guides (not shown), for efficient mixing of converging fluid streams.

In preferred configurations, the opposite expansion regions 620a, 620b are, as in the crosscut of FIGS. 6a-6b, of a triangular shape. The expansion regions 620a, 620b can be provided in a shape of an isosceles triangle, for example, with at least one inlet 610a, 610b, respectively, disposed at an angle between the congruent sides and opposite to an entrance to the transition region 630 (defined by a distance D1, FIG. 3). The distance D1 thus defines a base of the triangle. D1 also defines the maximal width (or height, depending on the fluid distributor orientation) of the fluid distributor 600.

The opposite expansion regions 620a, 620b comprise planar walls attached to each other and forming an enclosure serving as a flow channel therebetween. In certain embodiments, the opposite expansion regions 620a, 620b are formed within a flange structure. Each expansion region 620a, 620b is thus established by a compartment having an interior with a distance thereacross (width, in the direction of D1) gradually increasing between each inlet 610a, 610b and the transition region 320 (a distance indicated as d1) to an expansion width D1 in a direction of fluid flow F1, F2 (FIGS. 6a-6b). Due to the essentially triangular shape of the expansion regions 620a, 620b fluids propagate between the inlets 610a, 610b and the transition region 630, at the distance d1, to the expansion width D1, in accordance with an essentially outspread (radial) pattern; but within the limits defined by the interior of the compartments 620a, 620b.

Provision of the inlets 610a, 610b on any one of the expansion regions 620a, 620b is such that fluid streams F1, F2 propagate through the expansion regions 620a, 620b at a distance d1, essentially towards one another and towards the transition region 630. In some embodiments, the inlet(s) 610a on the expansion region 620a is/are arranged opposite to the inlet(s) 610b of the expansion region 620b, thus allowing the fluid streams F1, F2 to propagate towards one another from opposite directions.

By virtue of such features, as provision of the expansion regions 620a, 620b as substantially extended (“wing-shaped”) compartments having their width gradually increasing to reach the expansion width D1 at the distance d1 between the inlets 610a, 610b and the transition region 630, the profile of fluid flow (F1, F2) that propagates through the expansion regions 620a, 620b is laminar.

In embodiments according to FIG. 6a, the fluid distributor 600 is arranged in a vertical configuration. That is, the inlets 610a, 610b are positioned and separated from each other in a vertical direction. The vertical direction is parallel to the direction of the height of the substrate stack in the reaction chamber 120. Therefore, the spreading of fluid flows F1, F2 in the expansion regions 620a, 620b in the direction of D1 is in the direction of the planar surfaces of the substrates 130. Advantageously, lateral spreading of the fluid flow towards the outer edges in the plane of the substrate(s) 130 planes may be improved. Consequently, more homogeneous processing conditions may be achieved in the entire width of the reaction chamber 120. The advantageous fluid flow spreading is achieved in the fluid distributor 600 prior to reaching the reaction chamber 120.

In embodiments according to FIG. 6b the fluid distributor 600 is arranged in a horizontal configuration. That is, the inlets 610a, 610b are positioned and separated from each other in a horizontal direction. In the embodiments according to FIG. 6b, the fluid distributor 600 is rotated 90 degrees with respect to the orientation of the fluid distributors 600 according to the embodiments of FIG. 6a. The horizontal direction is parallel to the plane of the planar surfaces of the substrates 130 accommodated in the substrate holder 140 in the reaction chamber 120. Therefore, the spreading of fluid flows F1, F2 in the expansion regions 620a, 620b in the direction of D1 is in the direction of the height of the substrate stack. The fluid distributor 600 is configured to provide a fluid flow evenly distributed in the height direction of a substrate stack. Advantageously, vertical spreading of the fluid flow towards the uppermost and lowermost substrates in a stack may be improved. Consequently, the processing quality and conditions of high substrate stacks may be improved.

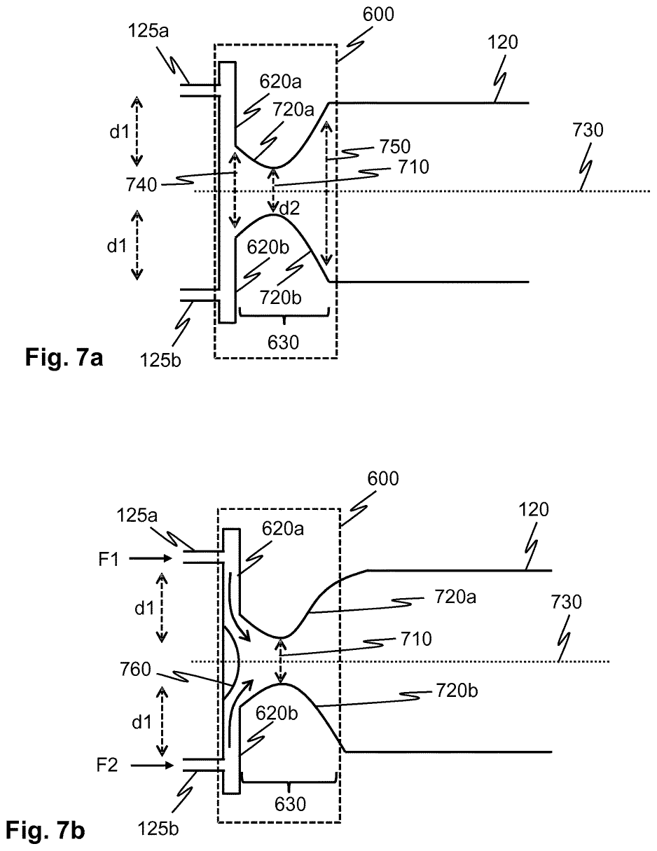

FIGS. 7a and 7b show a schematical cross-sectional side views of a transition region of a fluid distributor 600 (highlighted with a dashed box) having symmetrical and non-symmetrical transition region 630, respectively, according to certain embodiments. The transition region 630 is configured to receive and to combine fluid streams F1, F2 arriving thereto via the expansion regions 620a, 620b, respectively. At the transition region 630, the fluid streams F1, F2 arriving from the essentially opposite sides converge and mix. A combined fluid stream is formed, which is further directed into the reaction chamber 120.

Solid arrows in FIG. 7b depict the fluid flow F1, F2 to and in the fluid distributor 600. In the substrate processing apparatus 100, propagation of the fluid streams F1, F2 through the transition region 630 on their way from the expansion volume to the reaction chamber 120 is accompanied by change in direction of said fluid streams. By provision of the fluid distributor 600 according to the embodiments and by virtue of a relatively flat reaction chamber 120 provided as a confined space that encompasses a batch of substrates 130 arranged into a vertical stack, formation of jets, vortices and/or swirls in the fluid pattern propagating through the transition region 630 is minimized and laminar flow promoted. Precursor concentration is maintained essentially uniform when precursor fluid propagates, in the form of steady, laminar flow F, through the entire length of the reaction chamber and between the rotating substrates 130. Hence, all faces of the substrates 130 become deposited with a film having same thickness and uniform/even distribution of precursor molecules across the deposited surface(s).

Overall, implementation of the transition region 630 is such as to ensure efficient mixing of the streams F1, F2. Thus, all (wafer) substrates 130, downstream of the transition region 630, in the reaction chamber 120 become deposited with the uniform layer of precursor so that concentration of precursor is uniform across the individual substrate (planar) surface and across the surfaces of all substrates 130 in the batch/in the reaction space defined by the reaction chamber 120. Mixing is implemented, in the transition region 630, in a highly controlled manner, in an absence of vortex formation and without pressure losses, which further enables an efficient purge.

In certain embodiments, the dimensions of the transition region 630 in the direction of D1 (see FIGS. 6a-6b) substantially equals, depending on the fluid distributor 600 orientation, the width or the height of the substrates 130 accommodated in the substrate holder 140. In certain embodiments, the dimensions of the transition region 630 in the direction of D1 (see FIGS. 6a-6b) substantially equals, depending on the fluid distributor 600 orientation, the width or the height of the reaction chamber 120.

In the direction parallel to direction d1, the cross-section of the transition region 630 has a double-concave, or hour-glass-like shape. That is, walls 720a, 720b of the transition region 630 form a double-concave channel from the expansion volume to the reaction chamber 120. The walls 720a and 720b are opposite to each other. The other two walls, not visible in FIGS. 7a-7b, are preferably straight and in line with the walls of the reaction chamber, as seen for example, in FIGS. 3a-3b.

When entering the transition region 630 from the expansion volume, the walls 720a, 720b of the transition region 630 are gradually inclined, or narrow down, until to the narrowest point, the throat 710. The throat 710 has an essentially constant width d2 at the entire distance D1 (FIGS. 6a-6b). The throat 710 serves as a constriction zone. Thereafter, the transition region channel shape defined by the transition region walls 720a, 720b expands until to the width (or height, depending on the orientation of the fluid distributor) of the reaction chamber 120. Note that the FIGS. 7a-7b show the fluid distributor 600 in a vertical orientation, but the embodiments described are equally applicable to a fluid distributor 600 arranged in a horizontal orientation, such as shown in FIGS. 3a-3b and 4.

The transition region 630 and the throat 710 are implemented in such a way as to allow for efficient (convection and diffusive) mixing of fluids in laminar conditions. In said transition region 630, fluid streams F1, F2 arriving from essentially opposite directions are redistributed and recombined to form a combined flow, parallel to the longitudinal axis of the reaction chamber 120, in an absence of vortices or jets associated with turbulence. In certain embodiments, laminar mixing in the transition region 630 is attained by a distinctive configuration of the fluid distribution device 600 and the reaction chamber 120 as shown e.g. in FIGS. 7a and 7b.

Streams F1, F2 converge and mix at the transition region 630. The combined stream propagates into the reaction chamber 120 configured as a substantially flat, elongated body. In certain embodiments, the reaction chamber 120 has a constant cross-section (in the plane perpendicular to the longitudinal flow direction) throughout its entire length defined by its longitudinal axis (from its boundary with the transition regions indicated on FIG. 7a by reaction chamber opening, i.e., reaction chamber entrance, 750 to exhaust 190). The combined flow established at the entrance 750 to the reaction chamber 120 thus is laminar and propagates between the substrate surfaces (or side faces of the substrates) 130 through the length of said reaction chamber 120 (with essentially uniform velocity in certain embodiments). In other embodiments, the shape of the reaction chamber 120 curves inwards in the proximity of the exhaust 190.

The reaction chamber entrance (750) is formed to cause vertical spreading of the fluid flow entering the reaction chamber (120).

In certain embodiments, as shown in FIG. 7a, the transition region walls 720a, 720b of the transition region 630 form a symmetrical transition region channel. That is, the walls 720a, 720b are mirror symmetrical with respect to the longitudinal axis of the reaction chamber 730. Therefore, the curvature and angles of the walls 720a, and 720b are essentially identical. Advantageously, essentially identical fluid flow near and after the transition region wall 720a to the fluid flow near and after the transition region wall 720b to the reaction chamber 120 may be established. That is, fluid flow to the substrate regions located in or close to the extremities of the reaction chamber 120 in the direction parallel to d1 may receive essentially similar fluid flow from the transition region 630.

In certain embodiments, as shown in FIG. 7b, the transition region walls 720a, 720b of the transition region 630 form an asymmetrical transition region channel. That is, the walls 720a, 720b are not mirror symmetrical with respect to the longitudinal axis of the reaction chamber 730. Therefore, the curvature and/or the narrowing angles towards the throat 710 and/or expansion angles from the throat 710 towards the reaction chamber 120 of the walls 720a, and 720b differ from each other. That is, fluid flow to the extremities of the reaction chamber 120 in the direction parallel to the direction d1 may be different from each other. Advantageously, fluid flow to the reaction chamber 120 may be adjusted by the shape of the transition region 630 to take into account, for example, different flow environments at the bottom of the reaction chamber 120 (such as substrate holder 140 bottom and lid 180 structures) and top of the reaction chamber 120 (such as smooth reaction chamber top wall). Therefore, transition region geometry enables optimizing the fluid flow to the lateral or vertical reaction chamber extremities.

In certain embodiments, the transition region 630 begins at a transition region opening 740 and ends downstream of the throat 710. The transition region 630 in certain embodiments also comprises the reaction chamber entrance 750. In other embodiments, the transition region 630 ends at the reaction chamber entrance 750. In certain embodiments, the transition region opening 740 and the reaction chamber opening 750 are equal (in size). In certain embodiments, the transition region opening 740 and the reaction chamber opening 750 are not equal. In certain embodiments, the transition region opening 740 is larger than the reaction chamber opening 750. In certain embodiments, the transition region opening 740 is smaller than the reaction chamber opening 750. Further, each opening 740, 750 has a length extending at the distance D1 that corresponds to the expansion width of each sub-region 620a, 620b (FIG. 6a-6b).

Typically, the cross-sectional area at reaction chamber opening 750 is defined by the cross-sectional area of the reaction chamber 120, whereas the same at the transition region opening 740 can be a subject to design-related modifications. Hence, the width of the reaction chamber opening 750 typically corresponds to the width of the reaction chamber 120. The reaction chamber opening 750 thus outlines a boundary between the transition region 630 and the reaction chamber 120; therefore, said reaction chamber opening 750 can be further referred to as an entrance to the reaction chamber 120.

Additionally, the fluid distributor 600 may comprise additional appliances for promoting mixing of fluids F1, F2. For instance, the fluid distribution device 600 may comprise a flow-shaping element 760 (FIG. 7b) configured to adjust a flow direction of the fluid streams F1, F2 entering the transition region 630 so as to direct said streams essentially towards the reaction chamber 120. In certain embodiments, the flow-shaping element 760 is provided as an integral extension of the cover 810. In certain embodiments, the flow-shaping element 760 is provided as a separate part removably connectable to the interior of the cover 810. In certain embodiments, the flow-shaping element 760 has a cross-section of a shape of a dome, a triangle, a truncated triangle, or the like. In the fluid distributor 600 the element 760 is preferably arranged such that its crest (the most protruding, flow-shaping part) faces the reaction chamber 120.

The element 760 prevents the streams F1, F2, that arrive into the transition region 630 via the compartments 620a, 620b, from directly colliding at the transition region entrance 740; instead, the flow-shaping element 760 guides the streams F1, F2 towards the throat 710. The arrangement improves mixing rate and mixing uniformity.

FIG. 8 shows a schematical side view of a detachable cover 810 of a fluid distributor 600 according to certain embodiments. In certain embodiments, the fluid distributor 600 comprises a detachable cover 810. The cover may be attached, for example, by bolts. Advantageously, detachable cover 810 enables improved maintenance and cleaning of the fluid distributor 600. In certain embodiments, the cover 810 comprises attachment points 820a, 820b for the feedlines 125a, 125b.

FIGS. 9a-9c show schematical side, front, and top-view cross-sections of a substrate processing apparatus 100 configured to accommodate a high stack of substrates according to certain embodiments (an existing outer vacuum chamber omitted from FIGS. 9a-9c). In such embodiments, the fluid distributor is preferably at the horizontal configuration (such as in FIGS. 6b and 9b and 10a-10d), i.e., the fluid flow distribution in vertical direction, in the direction of substrate stack height, is maximized. In certain embodiments, the substrate processing apparatus is an apparatus according to embodiments of FIGS. 1-3 but comprises a reaction chamber 120 and a substrate holder 140 configured to accommodate a stack of 1-30 substrates 130.

In certain embodiments, a high stack of substrates is a stack of up to 30 substrates 130. In certain embodiments, a reaction chamber is configured to process a batch of up to 30 substrates at once. In certain embodiments, a liftable substrate rotating system 500 is configured to rotate the substrates 130 during processing and to move the substrates between a loading position and processing position. The lifting axle 160 of the liftable substrate rotating system 500 is visible in FIGS. 9a-9b. In certain embodiments, the liftable substrate processing system 500 comprises a substrate holder 140 configured to accommodate up to 30 substrates. In certain embodiments, the reaction chamber 120 comprises a substrate holder 140 configured to accommodate up to 30 substrates. In certain embodiments, the reaction chamber 120 is sealed by the lid 180 at the processing position. In certain embodiments, the reaction chamber is 120 is partially open, i.e., not sealed by the lid 180, at the processing position.

FIG. 9c shows a top view of fluid flow paths (solid arrows) across a substrate 130 in a reaction chamber 120. Due to less restriction by the substrate(s) at the sides, lowest fluid conductance occurs in the center of the substrate(s) 130. By rotating the substrate(s) more even conductance may be promoted.

A high substrate stack, for example of 30 substrates 130, causes additional challenge to provide sufficient fluid flow towards the uppermost and lowermost substrates from a single reaction chamber opening 750. To improve vertical fluid flow distribution to the reaction chamber 120, the fluid distributor may be arranged in horizontal configuration, i.e. to maximize spreading the fluid flow in the direction of the height of the substrate stack, as previously discussed with respect to, for instance, FIG. 6b. Therefore, the benefits of substrate rotation and fluid distributor may be combined to improve processing of high substrate stacks at once.

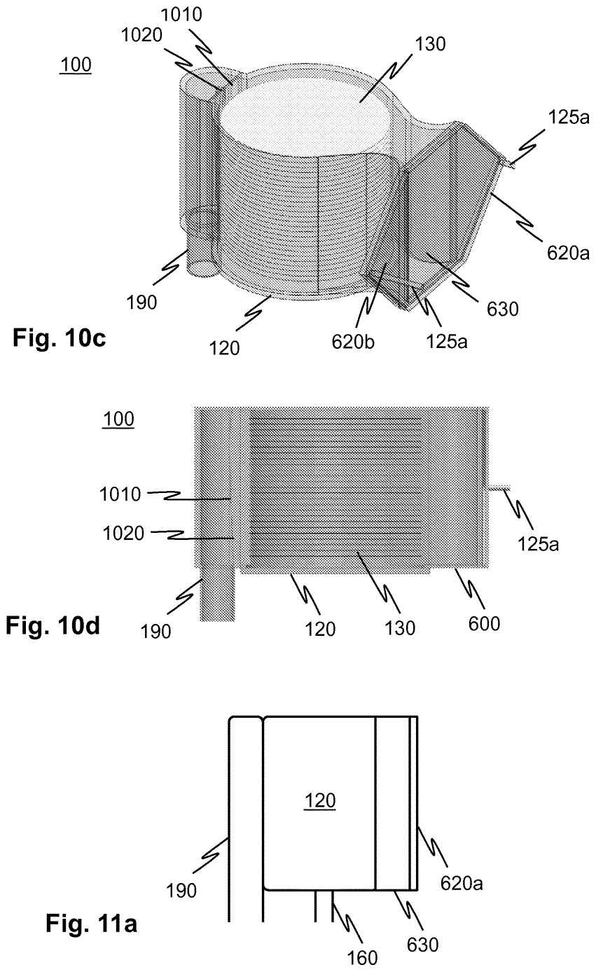

FIGS. 10a-10d show structural drawings of a substrate processing apparatus 100 according to certain embodiments configured to accommodate a high stack of substrates, such as a stack of up to 30 substrates 130.

In certain embodiments, the reaction chamber 120 shape is configured according to the substrates 130. For example, for round wafers (130), a round reaction chamber 120, the side walls of the reaction chamber having similar radius of curvature to the wafers (or the reaction chamber walls following the shape of the substrates 130), is preferred. Such a reaction chamber 120 with round walls is shown in FIGS. 10a-10d. Advantageously, empty space within the reaction chamber may be minimized. Further, flow conditions within the reaction chamber 120 may be made as uniform as possible.

In order to promote laminar fluid flow through the substrates 130 in a stack in a reaction chamber 120, the exhaust opening 1010 is modified accordingly. The exhaust opening 1010 is located on the back wall of the reaction chamber 120, opposite to the reaction chamber opening 750. In certain embodiments according to the FIGS. 10a-10d, the height of the exhaust opening 1010 extends across the full height of the reaction chamber 120. That is, the exhaust opening height matches the internal height of the reaction chamber 120.

In the embodiments according to FIGS. 10a-10d, the exhaust conduit 190 is connected to the exhaust opening 1010 of the reaction chamber 120 from below, at the bottom of the back of the reaction chamber 120. Therefore, the most suction from a vacuum pump 910 connected to the exhaust conduit 190 is experienced close to the bottom of the exhaust opening 1010. To enable homogeneous suction throughout the entire height of the exhaust opening 1010, the shape of the exhaust opening 1010 is adjusted. Thus, fluid conductance through the exhaust opening 1010 is adjusted by adjusting the shape of the exhaust opening 1010.

In certain embodiments according to FIGS. 10a-10d, the conductance through the exhaust opening 1010 is adjusted by a flow restricting feature, such as an exhaust block, 1020 arranged to the exhaust opening 1010. The outer shape of the exhaust opening 1010 is rectangular but an exhaust block 1020 extends across the entire height of the exhaust opening 1010 in the middle of the exhaust opening 1010. The exhaust block 1020 is widest close to the bottom of the exhaust opening 1010, i.e., closest to the vacuum conduit 190, and the exhaust block 1020 narrows upwards. Thus, gradually less of the exhaust opening 1010 is covered by the exhaust block 1020 going the higher from the bottom of the exhaust opening 1010 and the exhaust conduit 190. Therefore, the exhaust block 1020, by physically blocking fluid flow, evens out conductance and suction from the vacuum pump 910 through the exhaust opening 1010 at all heights.

In certain embodiments, the shape of the exhaust opening 1010 is configured according to the position of the exhaust conduit 190. Therefore, even suction through the exhaust opening at all reaction chamber 120 heights may be achieved regardless of the exhaust conduit 190 position.

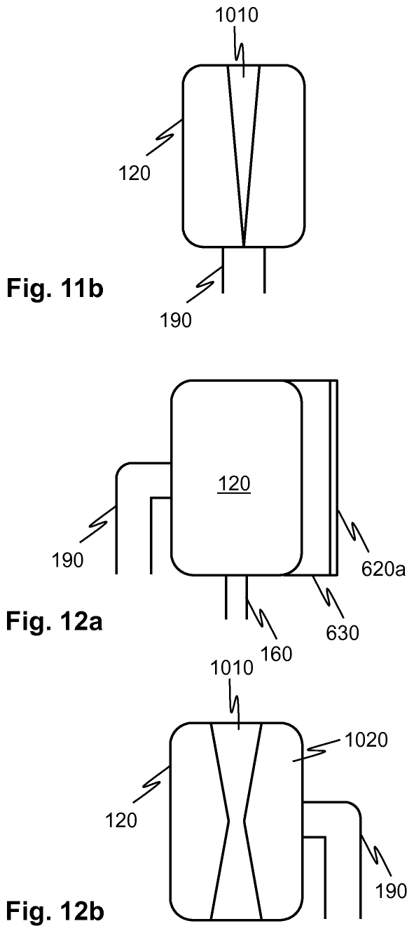

In certain embodiments according to FIGS. 11a-11b, the exhaust conduit 190 is connected to the reaction chamber 120 from the bottom of the back wall of the reaction chamber 120. Thus, the strongest suction is experienced at the bottom of the back wall of the reaction chamber 120 closest to the mouth of the exhaust conduit 190. In certain embodiments, to reduce suction at the bottom and gradually increase suction towards the top of the exhaust opening 1010, the exhaust opening is shaped as an inverted triangle, as shown in FIG. 11b. Thus, higher conductance may be achieved towards the top of the exhaust opening. As a result, even conductance over entire the height of the exhaust opening 1010 may be achieved due to shape of the exhaust opening 1010.

In certain embodiments according to FIGS. 12a-12b, the exhaust conduit 190 is connected to the middle of the back wall of the reaction chamber 120. Thus, the strongest suction is experienced at the middle of the back wall of the reaction chamber 120. In certain embodiments, to reduce suction in the middle and increase suction at the bottom and at the top of the exhaust opening 1010 to even out conductance, the exhaust opening 1010 is shaped in an hour glass-shape, as shown in FIG. 12b. Advantageously, even conductance over the height of the exhaust opening 1010 may be achieved.

As mentioned, the substrate holder 140 shown in various embodiments comprises vertical elements protruding from a base plate or from a lid part. The vertical elements are configured to support the substrates 130 so as to form a stack of substrates. In certain embodiments, the substrates 130 are fitted into a receiving structure or groove(s) provided by said vertical elements. In certain embodiments, the substrate holder 140 comprises two or more vertical elements. In certain embodiments, the substrate holder 140 comprises two vertical elements at opposite sides supporting the substrates. In certain embodiments, the substrate holder 140 is a one-part block, a monolithic piece (without welds or similar). In certain embodiments, the substrate holder 140 together with a main body part of the reaction chamber (which may also be a one-part block, a monolithic piece) form a sealed reaction chamber enclosure. In certain embodiments, this sealed reaction chamber enclosure in a closed configuration is only open at an inlet side to connect with the fluid distributor 600 (or opposite spreaders of the fluid distributor 600) and at an opposite outlet side for an exhaust conduit or connection 190. In certain embodiments, the substrate holder 140 (and the main body part of the reaction chamber) is manufactured by a one-part block manufacturing method, such as 3D-printing or similar. Such a reaction chamber (or main body part of the reaction chamber) is shown in FIG. 17.

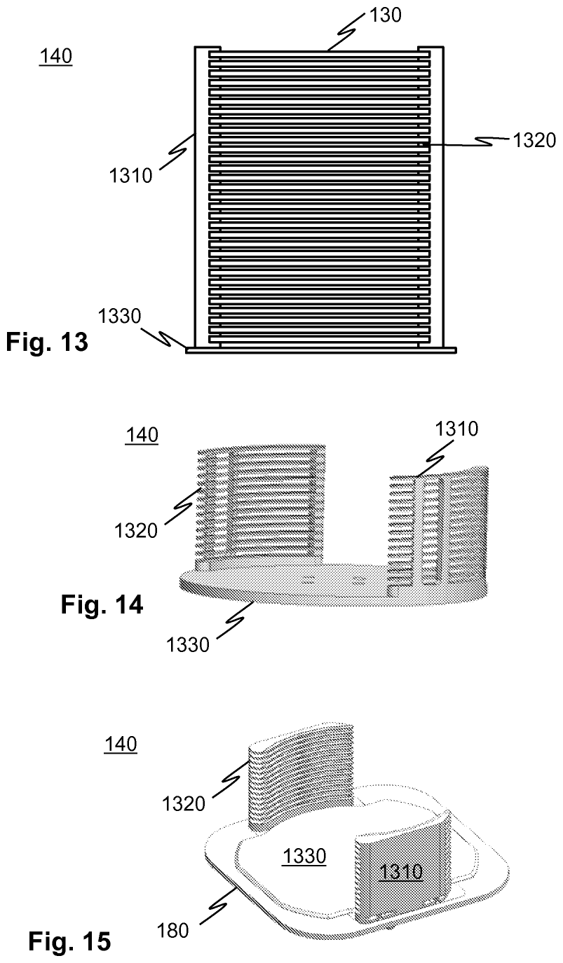

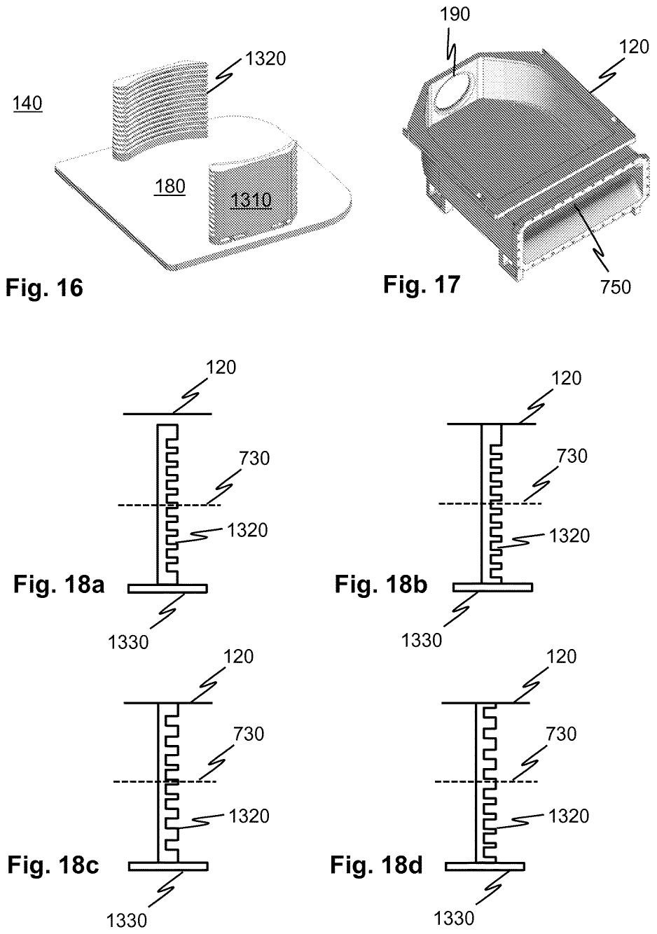

FIG. 13 schematically shows cross-sectional side view of a substrate holder according to certain embodiments configured to accommodate up to 30 substrates or even more. FIGS. 14-16 show substrate holders 140 according to certain embodiments.

In certain embodiments, the substrate holder (140) is monolithic. Accordingly, in certain embodiments the substrate holder (140) is manufactured of a single solid block of material. In certain embodiments, the substrate holder 140 comprise vertical elements 1310 configured to accommodate substrates 130, for instance, on ridges 1320 (or in grooves in between the ridges) of the vertical elements 1310. In certain embodiments, the substrate holder 140 comprises at least two vertical elements 1310. In certain elements, the substrate holder 140 comprises vertical elements to accommodate more than 15 substrates, or 25 substrates or more. In certain embodiments, the substrate holder comprises vertical elements to accommodate more than 15 substrates and up to 30 or 50 substrates. In certain embodiments, the vertical elements 1320 comprise ridges 1320 to accommodate the substrates 130. In certain embodiments, the substrate holder has the capacity of accommodating 1-20 substrates, in other embodiments up to 30 substrates 130.

In certain embodiments, the substrate holder comprises a base plate 1330. In certain embodiments, the substrate holder does not comprise a base plate 1330 but the lid 180 serves as a baseplate, i.e., as the closest surface to the lowermost substrate 130 accommodated by the substrate holder 140.

In certain embodiments, the substrate holder is removably attachable. In certain embodiments, the substrate holder 140 is removable from the external housing 110, for example, to be cleaned or loaded/unloaded outside the external housing 110 and/or the reaction chamber. The substrate holder 140 may be replaced by another substrate holder 140, for example, capable of accommodating a different number of substrates 130 or substrates 130 of different sizes.

In certain embodiments, the loading/unloading of the substrates the substrates 130 is performed automatically by a robotic loading arm. In certain embodiments, substrates are loaded 1, 2, 3, 4, or 5 substrates at a time. In certain embodiments, the loading/unloading is performed manually by a user. The removably attachable substrate holder 140 allows using substrate holders 140 configured to accommodate substrates 130 of different sizes, shapes and amounts in the liftable substrate rotating system 500 and the substrate processing apparatus 100. Also, the distance between adjacent substrates 130 to be rotated may be adjusted by choosing a substrate holder 140 having different spacing. Hence, several substrate-related processing parameters may be easily controlled and adjusted by selecting an appropriate substrate holder 140.

In certain embodiments, the substrate holder 140 is configured to hold a batch of 1-30 substrates 130. In certain embodiments, the substrate holder 140 has slots to hold a batch of 15 substrates 130.

In certain embodiments, the substrate holder 140 is configured to accommodate (circular) substrates 130 having diameter in the range from 100 to 1000 mm, preferably, 200 mm, most preferably 300 mm.

FIGS. 18a-18d schematically show detailed sections of a part of a substrate holder for a substrate processing apparatus according to certain embodiments. In certain embodiments, the substrates 130 are arranged in a substrate holder 140 such that the substrates 130 are equidistant from each other. In certain embodiments, the distances between the planar surface of the substrates 130 are not equal. In certain embodiments, the substrates 130 in a batch are arranged such that their planar surfaces are equally distanced from one another. That is the spacing (of ridges 1320) is equal.

In certain embodiments, the arrangement of the substrates 130 in the substrate holder 140 is mirrored, i.e., symmetrical with respect to the longitudinal axis of the reaction chamber 120. In certain embodiments, the arrangement of the substrates in the substrate holder is non-symmetrical with respect to the longitudinal axis of the reaction chamber 120.

In certain embodiments, the outermost substrates 130 in the batch, i.e., the substrates 130 having one of their planar sides facing walls (top and bottom) of the reaction chamber 120 at processing position, are distanced from said walls by essentially the same distance as provided between all substrates 130 in the batch. Advantageously, the environment perceived by the upper most wafer is essentially similar as the environment perceived by the bottom most wafer and the wafers within the stack.

In certain embodiments, the outermost sides of the outermost substrates 130 face the top wall of the reaction chamber 120 and the substrate holder 140 bottom surface located above the lid 180, respectively. In certain embodiments, the substrate holder 140 does not comprise a base plate 1330 between the lid 180 and the nearest substrate 130, such that one of the planar surfaces of the substrate faces directly the lid 180. The lid 180 forms the bottom wall of the reaction chamber 120 in the processing position.

In certain embodiments, the distance between the outer planar surfaces of the outermost substrates 130 in a batch and the reaction chamber 120 walls, or substrate holder 140 bottom surface, is not equal to the inter-substrate distance of the substrate holder 140. In certain embodiments, the distance to the reaction chamber 120 walls (and/or the substrate holder 140 bottom surface or the lid 180) from the outermost substrate surfaces is larger than the inter-slot distance. In certain embodiments, the distance of the top outermost substrate 130 and reaction chamber 120 wall and the distance of the bottom outermost substrate 130 and reaction chamber 120 wall are equal. In certain embodiments, the distance of the top outermost substrate 130 and reaction chamber 120 wall and the distance of the bottom outermost substrate 130 and reaction chamber 120 wall are non-equal. Advantageously, by controlling the distance to the reaction chamber 120 walls, gas flow to the outermost substrate surfaces 130 may be controlled.

In certain embodiments, the vertical elements 1310 of the substrate holder 140 extend beyond the substrate stack and contact the reaction chamber 120 wall(s) at the processing position. In certain embodiments, the vertical element(s) 1310 is/are in contact with the roof of the reaction chamber 120 (from the opposite end the substrate holder 140 is connected to the lid 180). In certain embodiments, the vertical element(s) 1310 is/are in contact with the floor of the reaction chamber 120 (from the opposite end the substrate holder 140 is connected to the lid 180). Advantageously, uppermost and lowermost substrates 130 may have similar processing conditions.

FIG. 18a schematically shows a vertical element 1310 of a substrate holder 140 configured to provide equal inter-substrate distance (i.e., ridge spacing). Further, the distance to the topmost and the lowermost substrates 130 to the reaction chamber 120 wall or the baseplate 1330 is different than the inter-substrate distance within the stack. Further the distance of the top most substrate 130 to the reaction chamber wall is larger than the distance from the lowermost substrate 130 to the baseplate 1330. Consequently, the substrate positioning is not mirrored with respect to the central axis 730 of the reaction chamber 120.

FIG. 18b shows a vertical element 1310 of a substrate holder 140 which extends from the baseplate 1330 to the roof of the reaction chamber at the processing position. However, the distance from the topmost substrate 130 to the roof is configured to be different than the distance from the lowermost substrate 130 to the baseplate 1330. Thus, the substrate positioning is not mirrored with respect to the longitudinal axis of the reaction chamber 120. The inter-substrate distance within the substrate stack is equidistant.

FIG. 18c shows a vertical element 1310 of a substrate holder 140 which extends from the baseplate 1330 to the roof of the reaction chamber at the processing position. The substrate positioning is mirrored with respect to the longitudinal axis of the reaction chamber 120. The ridges 1320 configured to hold the substrates 130 within the stack are not equidistant. The distance between the ridges 1320 is shortest close to the longitudinal axis 730 of the reaction chamber and is larger farther away from the axis 730. The distance from the topmost substrate 130 to the roof is equal to the distance from the lowermost substrate 130 to the baseplate 1330. However, the said substrate-wall distance is different from any of the inter-substrate distances.

FIG. 18d shows a vertical element 1310 of a substrate holder 140 which extends from the baseplate 1330 to the roof of the reaction chamber 120 at the processing position. The ridge spacing of the substrate holder 140 is not mirrored with respect to the longitudinal axis 730: the inter-substrate distance is shorter at the bottom and larger at the top. However, the distance from the topmost substrate 130 to the roof is equal to the distance from the lowermost substrate 130 to the baseplate 1330.

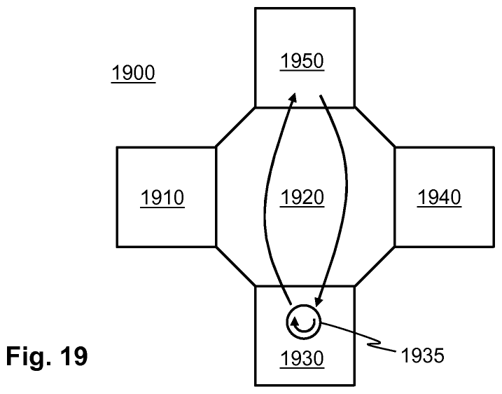

FIG. 19 schematically shows a substrate processing system. The system 1900 is configured to handle and process substrates under clean vacuum conditions.

In certain embodiments, the substrate processing system comprises a reception module 1920. The reception module 1910 is configured to load substrates 130, such as wafer(s) to the substrate processing system 1900. The substrates are also unloaded from the substrate processing system 1900 through the reception module 1910. In certain embodiments, the reception module 1910 comprises front opening unified pod(s), FOUP or similar, and an equipment front end module, EFEM.

In certain embodiments, the substrate processing system 1900 comprises a transfer unit 1920. The transfer unit comprises a robotic system for transferring the substrates 130 from one module to another without exposing the substrates 130 to the atmosphere outside the substrate processing system 1900.

In certain embodiments, the substrate processing system 1900 comprises a heating module 1930. The heating module 1930 is configured to heat the substrates 130 transferred therein by the transfer unit 1920. In certain embodiments, heating is applied to the substrates 130 before substrates 130 are transferred to a processing module 1950. In certain embodiments, substrate(s) 130 is/are transferred to the heating module 1930 in between processing cycles of the processing module 1950.

In certain embodiments, the substrate processing system 1900 comprises a cooling module 1940. The cooling module 1940 is configured to cool down the substrates 130 transferred therein by the transfer unit 1920. In certain embodiments, the substrates 130 are cooled down in the cooling module 1940 after being heated in the heating module 1930 and before being transferred to the processing module 1950, or before being unloaded from the system 1900.

The substrate processing system 1900 comprises a processing module 1950. In certain embodiments, the processing module 1950 is an ALD module. In certain embodiments, the processing module 1950 comprises a laminar flow reaction chamber 120 described in the foregoing. In certain embodiments, the processing module 1950 is comprises a substrate lifting system configured to transfer substrate(s) 130 between a loading position and a processing position. In certain embodiments, the processing module 1950 is comprises a liftable substrate rotating system 500. That is, the processing module 1950 may comprise, for example, a liftable substrate processing system 500, a fluid distributor 600, and a reaction chamber 120 configured to accommodate and process up to 30 substrates.

In certain embodiments, substrate(s) 130 is (are) transferred by the transfer unit 1920 from the processing module 1950, after a processing cycle or phase, to another module, rotated 180 degrees (in plane) and returned to the processing module 1950 for further processing. In certain embodiments, the heating module 1930 is provided with a rotating mechanism (of the type shown or a simpler rotation mechanism) 1935. Accordingly, in certain embodiments, substrate(s) 130 is (are) transferred by the transfer unit 1920 from the processing module 1950, after a processing cycle or phase, to the heating module 1930 for heating, rotated 180 degrees (in plane) and returned to the processing module 1950 for further processing. In certain embodiments, the rotating of the substrate(s) 130 is performed without heating. That is, the heating module 1930 may optionally serve as a rotating module. In certain embodiments, the substrate processing system 1900 comprises a dedicated rotating module (other than the heating module 1930).

Due to the dedicated rotating module or heating module 1930 with rotating capabilities, the substrates 130 may be processed equally from opposite directions by having two processing cycles without the need to rotate the substrates within the processing module 1950 or the reaction chamber 120. During the first processing cycle or phase, the fluid flow arrives to the substrate from first edge, and after rotating, during the second processing cycle or phase, from the direction of a second edge, opposite to the first edge. Advantageously, the processing module 1950 may be kept simple. Further, benefits of rotating the substrates 130 may be at least partially achieved even without a liftable substrate rotating system 500 in the processing module 1950.

In certain embodiments, the substrate processing system 1900 comprises a plurality of processing modules 1950. In certain embodiments, at least some of the processing modules comprise a laminar flow reaction chamber 120.

Overall, with the substrate processing system 1900 substrates 130 may be effectively handled under highly controlled and clean conditions.

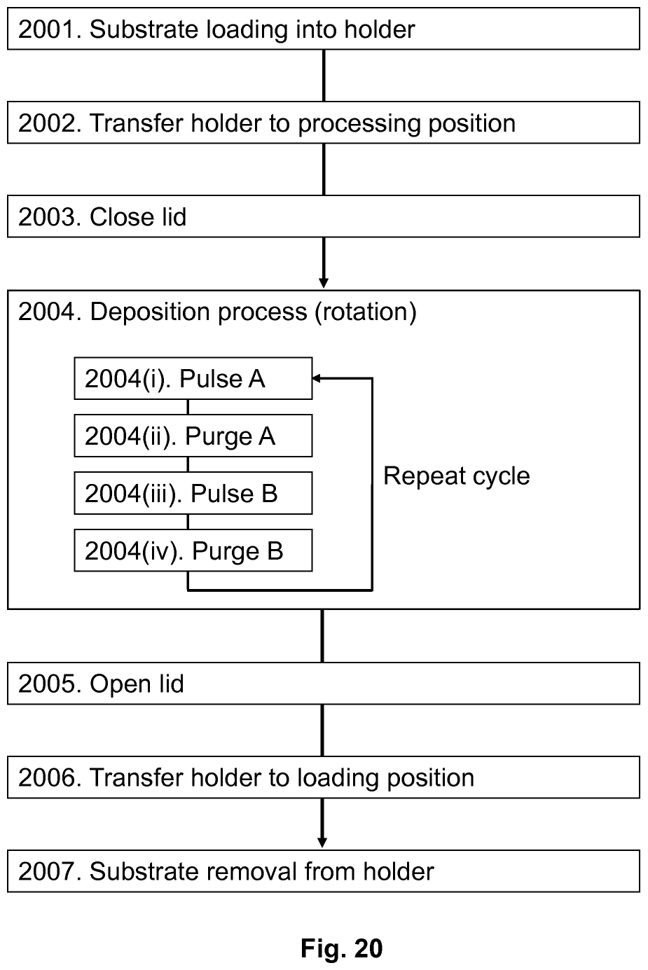

FIG. 20 shows a flow chart of substrate processing according to certain embodiments. In step 2001, a plurality of substrate wafers are loaded under vacuum by a loading robot into a substrate holder transferred to a loading position in a vacuum chamber. In certain embodiments, five substrates are loaded at a time so that altogether 30 substrates are accommodated by the substrate holder after six loading rounds. In other embodiments, another number of substrates may be loaded at a time. In step 2002, the substrate holder supporting the substrates is transferred to a processing position into a reaction chamber (housed by the vacuum chamber). In certain embodiments, the substrates are horizontally oriented in a vertical stack (substrate stack). In step 2003, a lid to the reaction chamber is closed (although in other embodiments, the lid may be left ajar). In certain embodiments, the substrate holder form the lid to the reaction chamber so that when the substrate holder is transferred to the processing position the substrate holder closes the reaction chamber (seals the reaction chamber in certain embodiments). In step 2004, deposition process steps are performed (in other embodiments, these may include etching). In certain embodiments, the process steps include ALD or MLD deposition steps. The process steps are performed under laminar flow conditions established by the apparatus geometry as described in the foregoing. In accordance with an example method, in step 2004(i), precursor vapor of a first precursor is pulsed (pulse A) into the reaction chamber. The precursor vapor flows as a laminar flow through the substrate stack and adheres by chemisorption onto the substrate surfaces forming a first half a monolayer of deposited material in a self-saturating (self-limiting) manner. The step 2004(i) is followed by a first purge period (purge A) during which inert gas flows through the substrate stack to purge the substrate surfaces in step 2004(ii). The step 2004(ii) is followed by a period, step 2004(iii), during which precursor vapor of a second precursor is pulsed (pulse B) into the reaction chamber. The precursor vapor flows as a laminar flow through the substrate stack and adheres by chemisorption onto the substrate surfaces forming a first full monolayer of deposited material. The step 2004(iii) is followed by a first purge period (purge B) during which inert gas flows through the substrate stack to purge the substrate surfaces in step 2004(iv). A first process cycle it thereby completed. The process cycles are repeated as many times as needed to obtain a desired thickness of deposited material. The substrate stack (or the substrate holder supporting the substrates) is rotated within the reaction chamber during deposition in order to improve uniformity. In certain embodiments, the substrate stack is rotated continuously (e.g. at a constant rotation speed). In other embodiments, said rotating comprises stepwise rotating, e.g., with an indexing mechanism (e.g., 90 or 180 degrees at a time). In certain embodiments, the substrate stack is rotated once 180 degrees halfway during deposition or 90 degrees at every quarter of a complete deposition sequence. Once the deposition process is complete (a desired thickness of deposited material is obtained through repeating the process cycles to complete a deposition sequence), the reaction chamber lid is opened in step 2005. In step 2006, the substrates are removed from the reaction chamber by transferring the substrate holder to the loading position (into the vacuum chamber, or into an intermediate space in between the reaction and vacuum chambers). In certain embodiments in which the substrate holder forms the lid to the reaction chamber, the substrate holder opens the lid upon being transferred to the loading position. Finally, in step 2007, the substrates are unloaded from the substrate holder (under vacuum) by the loading robot (e.g., five substrates at a time). In certain other embodiments, instead of processing a stack of substrates only a single substrate is processed within the reaction chamber.

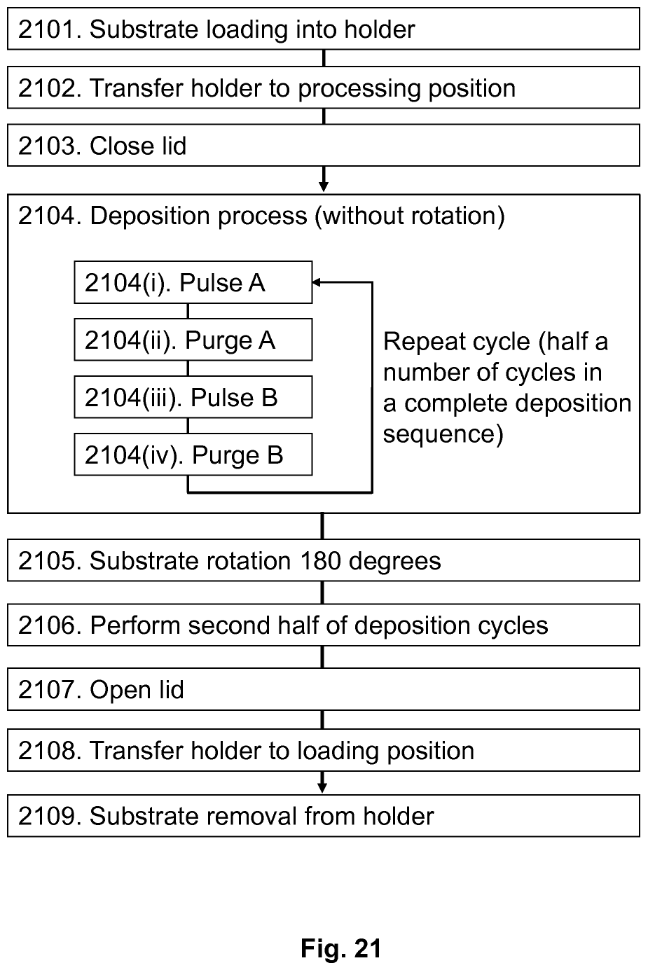

FIG. 21 shows a flow chart of substrate processing according to certain other embodiments. The method shown in FIG. 21 otherwise corresponds to the method shown in FIG. 20 except that instead of rotating within the reaction chamber, the rotation is implemented outside of the reaction chamber. Accordingly, in step 2101, the substate(s) is (are) loaded under vacuum by a loading robot into a substrate holder transferred to a loading position in a vacuum chamber. In steps 2102 and 2103, the substrate holder is transferred to a processing position into a reaction chamber (housed by the vacuum chamber) and the lid to the reaction chamber is closed (these steps may occur simultaneously as described). In step 2104, deposition process steps are performed. In certain embodiments, the process steps include ALD or MLD deposition steps. The process steps are performed under laminar flow conditions established by the apparatus geometry as described in the foregoing. In accordance with an example method, in step 2104(i), precursor vapor of a first precursor is pulsed (pulse A) into the reaction chamber. The step 2104(i) is followed by a first purge period (purge A) in step 2104(ii). The step 2104(ii) is followed by a period, step 2104(iii), during which precursor vapor of a second precursor is pulsed (pulse B) into the reaction chamber. The step 2104(iii) is followed by a first purge period (purge B) in step 2104(iv). These process cycles are repeated half a number of a complete deposition sequence. The reaction chamber lid is then removed, the substrate(s) is (are) removed from the reaction chamber, rotated 180 degrees outside of the reaction chamber, and returned back to the reaction chamber (step 2105). Thereafter, a second half of the deposition cycles is performed (step 2106). Once the deposition process is complete (a desired thickness of deposited material is obtained through repeating the process cycles to complete a deposition sequence), the reaction chamber lid is opened and the substrate(s) is (are) removed from the reaction chamber by transferring the substrate holder to the loading position (in steps 2107 and 2108, which may occur simultaneously). Finally, in step 2109, the substrate(s) is (are) unloaded from the substrate holder (under vacuum) by the loading robot.

The 180 degrees rotation halfway the processing is implemented e.g. by transferring the substrates to another module of a deposition apparatus or cluster for rotation. Said another module in certain embodiments comprises a rotating mechanism, such as an indexing mechanism. Accordingly, in certain embodiments, said another module may be the heating module 1930 or similar. In certain other embodiments, the 180 degrees rotation is performed by the loading robot. In such embodiments, the loading robot receives the substrate(s) from the substrate holder (at the loading position), rotates the substrate(s) 180 degrees and returns the substrate(s) to the substrate holder (for subsequent transfer to the reaction chamber for further processing). The loading robot may be part of the robotic system of the transfer unit 1920 or similar.

In certain embodiments, a TiO₂ film was deposited from a titanium-containing precursor (TiCl₄) and an oxygen-containing precursor (H₂O or O₃) and it was observed that thin film uniformity was improved when the substrate (sample) was rotated 180 degrees halfway during deposition compared to a non-rotated sample.

Without limiting the scope and interpretation of the patent claims, certain technical effects of one or more of the example embodiments disclosed herein are listed in the following. A technical effect is avoiding deposition faults arising from irregular deposition rates on the substrates in the stack (caused by potential non-uniform and/or turbulent behavior of the precursor fluid flow between the substrates) which are common to conventional chemical deposition reactors. Further technical effect is more uniform film deposition using non-ideal ALD chemistries.

Various embodiments have been presented. It should be appreciated that in this document, words comprise, include, and contain are each used as open-ended expressions with no intended exclusivity.

The foregoing description has provided by way of non-limiting examples of particular implementations and embodiments a full and informative description of the best mode presently contemplated by the inventors for carrying out the invention. It is however clear to a person skilled in the art that the invention is not restricted to details of the embodiments presented in the foregoing, but that it can be implemented in other embodiments using equivalent means or in different combinations of embodiments without deviating from the characteristics of the invention.

Furthermore, some of the features of the afore-disclosed example embodiments may be used to advantage without the corresponding use of other features. As such, the foregoing description shall be considered as merely illustrative of the principles of the present invention, and not in limitation thereof. Hence, the scope of the invention is only restricted by the appended patent claims.

1. An apparatus, comprising:
a main body part of a laminar flow reaction chamber comprising an inlet opening for precursor gas at its front side, an exhaust opening at its rear side, and a lid opening at its top or bottom side; and
a substrate holder configured to accommodate a batch of substrates, the surfaces of the substrates facing each other thus forming a substrate stack, the substrate holder forming a lid to cover the lid opening.

2. The apparatus of claim 1, wherein the inlet opening is reaction chamber wide or reaction chamber high.

3. The apparatus of claim 1, comprising a throat downstream the inlet opening.

4. The apparatus of claim 3, wherein the throat is a concave throat.

5. The apparatus of claim 4, wherein the throat is symmetrical.

6. The apparatus of claim 4, wherein the throat is asymmetrical.

7. The apparatus of claim 1, wherein side walls of the main body part of the reaction chamber curve inwards towards the exhaust opening.

8. (canceled)

9. (canceled)

10. The apparatus of claim 7, wherein the side walls of the main body part of the reaction chamber are free from flow obstacles.

11. The apparatus of claim 1, wherein the main body part of the reaction chamber is monolithic.

12. The apparatus of claim 1, wherein the substrate holder is monolithic.

13. (canceled)

14. The apparatus of claim 1, wherein the substrate holder comprises two opposite protruding parts protruding from the substrate holder and being configured to support the substrates.

15. (canceled)

16. (canceled)

17. The apparatus of claim 14, wherein the substrate holder comprises a smooth planar lid part, and the opposite protruding parts protrude from the smooth planar lid part to accommodate substrate(s).

18. The apparatus of claim 14, wherein the two opposite protruding parts follow the shape of a round substrate.

19. The apparatus of claim 14, wherein the two opposite protruding parts comprise ridges or grooves to accommodate the substrates.

20. The apparatus of claim 19, wherein the spacing of the ridges or grooves is equal or unequal.

21. The apparatus of claim 1, wherein the closest distance from an outermost substrate to its closest reaction chamber wall is different from or same as a closest distance between adjacent substrates.

22. The apparatus of claim 1, comprising an exhaust line in or attached to the main body part of the reaction chamber.

23. The apparatus of claim 22, wherein the exhaust line takes a turn.

24. The apparatus of claim 23, wherein the turn is perpendicular to the direction of the laminar flow.

25. The apparatus of claim 23, wherein the turn is 90 degrees.
